(19) United States
(12) Patent Application Publication
(10) Pub. No.: US 2026/0212484 A1
(43) Pub. Date: Jul. 23, 2026

(54) Systems and Methods for Design Rules Based Alignment and Metrology

(71) Applicant: Golden Aspen Technologies, Inc., Centennial, CO (US)

(72) Inventor: Li Shu, Centennial, CO (US)

(21) Appl. No.: 19/371,854

(22) Filed: Oct. 28, 2025

Related U.S. Application Data
(60) Provisional application No. 63/712,776, filed on Oct. 28, 2024.

(51) Int. Cl. G06T 7/00; H10P 74/20

(52) U.S. Cl. CPC G06T 7/0006; G06T 7/001; H10P 74/20; G06T 2207/30148

(57) ABSTRACT

An object (such as a wafer or chip) can be aligned using design rules, where a region of the object (which can be the entire object) is divided into two (or possibly more) adjacent sections, where components/elements are formed in each section according to respective design rules designated for each section. For a pair of adjacent sections, the respective design rules specify respective periodicities of the components/elements therein, where the periodicities are different from each other and also from that of a reference pattern/signal. Respective moire patterns are generated for each section from a superimposition of an image of the components/elements in that section and the reference pattern/signal. The distance between respective peaks in the respective moire patterns can indicate a displacement needed to align the two sections, facilitating alignment of the object.

### CROSS-REFERENCE TO RELATED APPLICATIONS

This application is related to and claims the benefit of priority to U.S. Provisional Patent Application Ser. No. 63/712,776, titled Systems and Methods for Design Rules Based Alignment and Metrology, filed on Oct. 28, 2024, the entirety of which is incorporated herein by reference.

### FIELD OF THE INVENTION

This disclosure generally relates to optical alignment techniques, and more specifically to computationally efficient techniques for aligning semiconductor chips and/or wafers and portions thereof, during semiconductor device fabrication.

### BACKGROUND

In microchip fabrication, the alignment of subsequent layers of material—as superimposed over each layers of the lithographic (litho) process—is required to be within a fraction (<⅓) of the critical dimension (CD). As CD falls below 3 nanometers (nm), the alignment requirement falls below 1 nm—as a comparison, 1 nm is approximately the width of 5 atoms.

Precision alignment is traditionally achieved in two steps: first with wafer markings for gross alignment; then using alignment patterns—usually placed in the saw lanes between chips—for fine alignment. Alignment patterns supporting moire effects—which served to amplify any misalignment have been proposed and tested previously.

Silicon based material has coefficient of thermal expansion (CTE) in single digits of ppm (on the order of 10⁻⁶). For a chip with dimension in the millimeter (mm), this amounts to multiple of nm variations per degree of kelvin in temperature variation—which is comparable to CD in single digit of nm.

Compounding this with varying CTEs of different material layering—and with the number of layers in modern chips reaching multiple of 100s—not appropriately managing and adapting to thermal variability between fine alignment and litho process can significantly affect yield. A current strategy to manage the effect of thermal variability is to place additional alignment patterns inside each chip. This serves to reduce the dimensional multiplier of the CTE—and with enough such patterns, the distance between adjacent ones can reduce the associated thermal variability to within a fraction of alignment requirements.

### SUMMARY

One cost of this strategy is that alignment patterns take away significant real estate as they each are usually in the multiple of 100 nm in each dimension. Additionally, these patterns can only measure the total thermal variability between adjacent alignment patterns, more detailed understanding requires greater number of such patterns. There is also the additional effect that devices and connections need to be built around the areas occupied by these alignment patterns. A more efficient approach to detect, measure and manage thermal variabilities in the alignment and litho process may be highly desirable.

In this document, we propose a new approach to this alignment process which does not require alignment patterns inside chip area. Instead, we propose to use adjustments to design rules (for material layering) to support engaging moire effect-extending the usability, accuracy, and/or computational efficiency of alignment. In particular, a region of a wafer or chip is selected. The selected region need not be but can be the entire wafer or chip. Then two, and possibly more than two, sections (also called sub-sections, depending on the context) are formed within the selected region. One or more design rules are applied to each section, such that the periodicity of chip elements (e.g., wires, cells, semiconductor layers, metallization layers, etc.) to be fabricated in one section is different from that of the chip elements to be formed in the other section. For each section, a respective moire pattern is generated by superimposing an image of the elements in that section with a reference pattern or signal having a period that is different from the periods associated with either section. The distance between respective peaks in the respective moire patterns can be used to determine alignment of the two sections, and thus the alignment of the chip and/or wafer.

### BRIEF DESCRIPTION OF THE DRAWINGS

Various embodiments of the invention disclosed herein are illustrated by the way of non-limiting examples in the accompanying drawings in which:

FIGS. 1A and 1B show respective frequency-domain representations of sinusoidal waveforms having frequencies f₀ and f₁, respectively;

FIG. 1C shows a frequency-domain representation of the convolution of two sinusoidal waveforms having frequencies f₀ and f₁;

FIG. 2 schematically depicts a moire pattern resulting from superimposition of two sets of regularly spaced parallel lines, where the two sets are disposed at an angle relative to each other, i.e. the two sets are not themselves parallel to each other;

FIG. 3A shows frequency-domain representations of sinusoidal waveform having frequency f₁;

FIG. 3B shows frequency-domain representations of sinusoidal waveform corresponding to FIG. 3A, but rotated at an angle;

FIG. 3C shows a frequency-domain representation of the convolution of two sinusoidal waveforms corresponding to FIGS. 3A and 3B;

FIG. 4A is a representation of the dominant spatial frequencies of a 2D regular rectangular grid corresponding to one pair of two sets, S11, S12, of parallel lines, where S12 is perpendicular to S11;

FIG. 4B is a representation of the dominant spatial frequencies of 2D regular rectangular grid corresponding to another pair of two sets, S21, S22, of parallel lines, where S22 is perpendicular to S21, and S21 is at an angle with respect to S11 of FIG. 4A, and is not parallel to or perpendicular to S11;

FIG. 4C is a representation of a convolution of the sets S11, S12, S21, and S22 of FIGS. 4A and 4B;

FIG. 5A depicts an impulse train with one spacing corresponding to one period;

FIG. 5B depicts a cosine function with periodicity different from the period of the impulse train of FIG. 5A;

FIG. 5C depicts a convolution of patterns corresponding, respectively, to the impulse train of FIG. 5A and the sinusoid (cosine function) of FIG. 5B;

FIG. 6 illustrates the convolution of two impulse trains that have different fundamental spatial frequencies (i.e., different periodicities), and the respective patterns corresponding to the impulse trains are at a rotational mismatch, i.e., the patterns are at an angle but are neither parallel nor perpendicular to each other;

FIG. 7 schematically depicts a region of an object having two sections that include respective periodic patterns, where the respective periods of the two patterns are different;

FIG. 8 schematically depicts the region of FIG. 7, where the respective patterns of the two sections are incomplete;

FIG. 9 schematically depicts an adjustment performed according to one embodiment to align the two sections of FIG. 7;

FIG. 10 schematically depicts a region having several sections in the X and Y directions, where those sections are designated with respective periods, where a periodic structure fabricated within a particular section uses the period designated for that section;

FIG. 11 schematically depicts a region of a semiconductor chip having sections according to those of FIG. 10;

FIG. 12 schematically depicts a region of a semiconductor chip having a number of sections, some of which are designated as critical and are associated with design rules to be used for section/chip/wafer alignment, according to various embodiments;

FIG. 13A schematically depicts a section of a semiconductor chip within which an array of elements is to be fabricated; and

FIG. 13B illustrates sub-sectioning of the section depicted in FIG. 13A, where the sub-sections are associated with corresponding design rules, according to one embodiment.

### DETAILED DESCRIPTION

### I. Introduction

Moire pattern, also known as moire fringe, are large scale interference patterns resulting from mismatch of fine patterns. The name moire originally referred to a lace-type of textile formed by pressing two layers together. In pre-industrial age production, the imperfect fine spacing in the layers results in characteristic larger scale pattern, which became known as moire pattern. Over the years, it was studied in lithographic (dot-based) printing and digital printing and display—as nuisance effect to be compensated and overcome; and it was later used in measurements of machined surfaces, quantum material super lattices, and for alignment and metrology in micro-chip fabrication, where this scale amplification property of moire effect became useful.

In alignment of chip masks, we are interested specifically in two types of mismatch: translational and rotational misalignment. To base our discussion, we will first present a particular approach to analyzing and understanding moire effect—on which our proposed extension are based; we then present a set of extensions which enhance the accuracy and/or efficiency of the alignment and the alignment process.

### II. Moire Effect

Precise analysis and understanding of moire effect is dependent on the base pattern. For our application, we will focus on lines and 2D grids formed by perpendicular lines. For our purposes, we will accompany the discussion with a set of understanding from the Fourier frequency domain. As will be seen in later sections, this set of understanding facilitated insights which lead to our proposed extension.

### A. Moire Effect of Parallel Lines

The moire pattern created by two sets of parallel lines—when in perfect rotational alignment—is akin to the beading of two sinusoidal signals. We will start with this simple case and then delve into the cases when they are in rotational mis-alignment below.

For ease of discussion, we will call the two signals and/or patterns forming the moire pattern the base signals or base patterns.

### 1) Moire Effect of Two Sinusoidal Signals as Beading

Mathematically, the superimposition of two sinusoidal signals, one at frequency f₀ and the other at f₁ can be written as the sum of two sinusoids by the product-angle formula. For simplicity, we will omit the phase angle difference in these discussions because they do not materially alter the understanding. Specifically:

$$cos ( 2 π {f}_{0} t ) cos ( 2 π {f}_{1} t ) = \frac{1}{2} ( cos ( 2 π Δ f t ) + cos ( 2 π ( {f}_{0} + {f}_{1} ) t ) ) where \qquad ( 1 )$$

$$Δ f = \vert {f}_{0} - {f}_{1} \vert \qquad ( 2 )$$

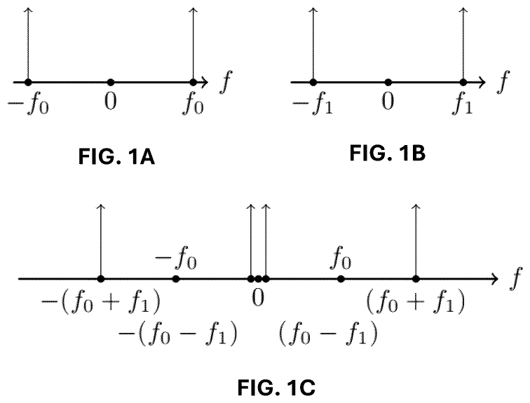

The Fourier transform of a real sinusoidal signal includes two Dirac delta impulse functions at positive and negative of its frequency, as shown in FIGS. 1A and 1B. Since the product of two functions is the convolution of their Fourier transforms, the product in (1) includes, in frequency domain, 4 Dirac Delta impulses at the positive and negative sum and difference of the two frequencies—as illustrated in FIG. 1C. This convolution of impulse functions in the frequency domain is the essence of moire effect.

Specifically, when f₀ and f₁ are both fairly large but are very close to each other, their difference Δf is close to 0 while their sum is twice their original. When the high frequency component is either implicitly or explicitly filtered or filtered out, the resulting low frequency sinusoid reveals the frequency mismatch Δf.

When viewed in time domain, this frequency mismatch is seen as the amplification of the period T=1/f. Specifically, the wavelength of the low frequency component in (1) is given by:

$$Δ T = \frac{1}{Δ f} = \frac{1}{\vert {f}_{0} - {f}_{1} \vert} = \frac{1}{\vert 1 / {T}_{0} - 1 / {T}_{1} \vert} = \frac{{T}_{0} {T}_{1}}{\vert {T}_{0} - {T}_{1} \vert} \qquad ( 3 )$$

This is the essence of moire effect.

In particular, the resulting moire pattern can be isolated by removing the higher frequency components in the resulting superimposition, at f₀+f₁. In practice, this can be implicitly accomplished—e.g. because the higher frequency is outside of the observable range of instruments used—or explicitly by some filtering process or mechanism. For brevity, we will implicitly assume that this is taking place and omit explicit discussion of this step in the rest of this document except when necessary.

### 2) Moire Effect of Two Sets of Parallel Lines

The moire effect of two sets of superimposed parallel lines, regularly spaced respectively with spacing d₀ and d₁, when in rotationally alignment, is very similar to the 2 sinusoids. In particular, we may consider such regularly spaced parallel lines as the extension of a 1D square wave signal into a 2^{nd} dimension. We know that such a square wave corresponds to a Fourier series at integral multiple of its periodicity. Applying the same convolution theorem to the superimposition of two such square waves leads to similar understanding of having the dominant low frequency component at the difference of their periodicities.

Corresponding to the above understanding, the spatial beading of parallel lines with regular spacing is also given by (3), specifically

$$Δ d = \frac{{d}_{0} {d}_{1}}{\vert {d}_{0} - {d}_{1} \vert} \qquad ( 4 )$$

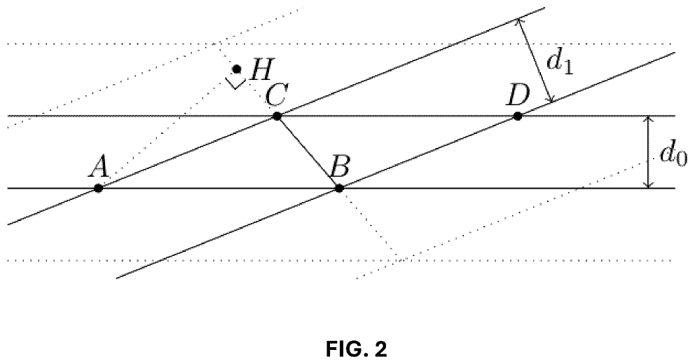

When not in rotational alignment, these two sets of regularly spaced parallel lines superimpose to create a regular pattern of parallelograms. As depicted in FIG. 2, along its short diagonal there is a greater concentration of intersections. This creates the parallel lines in the resulting moire effect. Notice that the corners marking the ends of the long diagonal also mark the short diagonals for adjacent parallelograms. So the corners of each parallelogram marks two periods of the moire pattern. To help develop a more intuitive feel, it is illustrative to follow through a quick derivation of quantities of interest.

As depicted in FIG. 2, let α=∠CAB be the misalignment angle between the two sets of regularly spaced parallel lines. Let ∥\vec{AC}∥ and ∥\vec{AB}∥ respectively denote the length of line segment AC and AB, which are the two sides of the parallelogram. We have:

$$‖ \overleftarrow{AC} ‖ = {d}_{0} / sin ( α ) \qquad ( 5 )$$

$$‖ \overleftarrow{AB} ‖ = {d}_{1} / sin ( α )$$

Using the cosine law, we may compute the length of line segment BC as:

$$‖ \overleftarrow{BC} ‖ = \sqrt{{‖ \overleftarrow{AC} ‖}^{2} + {‖ \overleftarrow{AB} ‖}^{2} - 2 ‖ \overleftarrow{AC} ‖ ‖ \overleftarrow{AB} ‖ cos ∠ CAB} = \sqrt{{( \frac{{d}_{0}}{sin ( α )} )}^{2} + {( \frac{{d}_{1}}{sin ( α )} )}^{2} - 2 \frac{{d}_{0}}{sin ( α )} \frac{{d}_{1}}{sin ( α )} cos ( α )} = \frac{1}{sin ( α )} \sqrt{{d}_{0}^{2} + {d}_{1}^{2} - 2 {d}_{0} {d}_{1} cos α} \qquad ( 6 )$$

Let H be such that AH is the height of the triangle ΔACB from A. From the analysis in the above, we know that ∥\vec{AH}∥ is the spacing of the moire pattern, which we will refer to as Δdᵣ following the notation used in the above.

Computing this triangle's area using AB and BC as base, set them equal, we have:

$$\frac{1}{2} ‖ \overleftarrow{AB} ‖ {d}_{0} = \frac{1}{2} \frac{{d}_{1}}{sin ( α )} {d}_{0} = \frac{{d}_{0} {d}_{1}}{2 sin ( α )} = \frac{1}{2} ‖ \overleftarrow{BC} ‖ ‖ \overleftarrow{AH} ‖ \qquad ( 7 )$$

Solve for ∥\vec{AH}∥ and substitute in (6), we have:

$$Δ {d}_{r} = ‖ \overleftarrow{AH} ‖ = \frac{{d}_{0} {d}_{1}}{sin ( α )} / ‖ \overleftarrow{BC} ‖ = \frac{{d}_{0} {d}_{1}}{\sqrt{{d}_{0}^{2} + {d}_{1}^{2} - 2 {d}_{0} {d}_{1} cos α}} \qquad ( 8 )$$

Let δᵣ denote the angle of the moire lines. From FIG. 2, we see that

$${δ}_{r} = π - ∠ A B C \qquad ( 9 )$$

To compute this angle, we use the sine law within ΔABC. Specifically:

$$\frac{‖ \overleftarrow{B C} ‖}{sin α} = \frac{‖ \overleftarrow{AC} ‖}{sin ∠ ABC} \qquad ( 10 )$$

Solve for sin ∠ABC, and substitute in (6), we have:

$$sin ∠ ABC = \frac{‖ \overleftarrow{AC} ‖}{‖ \overleftarrow{BC} ‖} sin α = \frac{{d}_{0} sin α}{\sqrt{{d}_{0}^{2} + {d}_{1}^{2} - 2 {d}_{0} {d}_{1} cos α}} \qquad ( 11 )$$

Substitute into (9), we have:

$${δ}_{r} = π - arcsin ( \frac{{d}_{0} sin α}{\sqrt{{d}_{0}^{2} + {d}_{1}^{2} - 2 {d}_{0} {d}_{1} cos α}} ) \qquad ( 12 )$$

Note that for α small, cos α approaches 1. The square root term in the denominator approached |d₀−d₁|. And we have the following for (8) and (12)

$$Δ {d}_{r} \approx \frac{{d}_{0} {d}_{1}}{\vert {d}_{0} - {d}_{1} \vert} \qquad ( 13 )$$

$${δ}_{r} \approx π - arcsin ( \frac{{d}_{0}}{\vert {d}_{0} - {d}_{1} \vert} sin α ) \approx π - \frac{{d}_{0}}{\vert {d}_{0} - {d}_{1} \vert} α \qquad ( 14 )$$

where the last approximation uses sin α≈α for a small. Note that the amplification factor of

$$\frac{{d}_{0}}{\vert {d}_{0} - {d}_{1} \vert}$$

in both spacing and angle of resulting moire pattern, corroborating (4).

On the other hand, as α grows bigger, cos α deviates from 1. This led to growth in that square root term. To illustrate the point, consider α=π/3, when cos α=½, that square root term becomes

$$\sqrt{{d}_{0}^{2} + {d}_{1}^{2} - {d}_{0} {d}_{1}} .$$

Suppose d₀ and d₁ are very close in magnitude, this square root term would approach one of the d's. And we would have:

$$Δ {d}_{r} \approx {d}_{0} \approx {d}_{1}$$

$${δ}_{r} \approx π - α$$

which is completely void of any amplification effect.

In simulation, the amplification effect in such rotational mismatch rapidly diminishes as the angle grows beyond a few degrees. This generally does not cause any problems as there are many ways to detect and manage gross rotational misalignment. It is the small misalignments which are difficult to detect and manage in practice—and this is where the amplification factor in the moire effect can really shine.

Finally, we note that (8) and (12)—also their approximation in (13) and (14) when a is small—can both be used to estimate mismatch rotation angles respectively from the measured moire pattern spacing and moire pattern line rotation angles. When both measurements are available, their estimates may be combined appropriately.

### 3) Frequency Domain Interpretation of Rotational Mismatch

We know that rotation of a 2D image results in rotation of its 2D Fourier transform by the same amount.

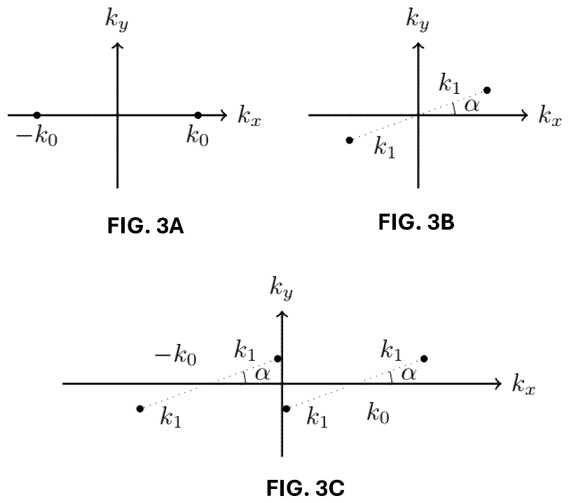

Let k₀ and k₁ respectively denote the spatial frequency of the two sinusoidal patterns—extension of 1D sinusoidal signals to a 2^{nd} dimension—with a relative rotation angle α. Attributing the rotation to the latter pattern, their Fourier transforms and the Fourier transform of their superimposition are illustrated in FIGS. 3A-3C.

The moire pattern contains the low frequency component, which corresponds to the two spots closest to the origin: (−k₀+k₁ cos α, k₁ sin α) and (k₀−k₁ cos α, −k₁ sin α). Notice they are symmetric around the origin—a necessity to produce a real pattern.

Its spatial wavelength Δkᵣ and rotation angle δᵣ are respectively given by

$$Δ {k}_{r} = \sqrt{{( {k}_{0} - {k}_{1} cos α )}^{2} + {( {k}_{1} sin α )}^{2}} = \sqrt{{k}_{0}^{2} + {k}_{1}^{2} - 2 {k}_{0} {k}_{1} cos α} \qquad ( 15 )$$

$${δ}_{r} = π - arcsin \frac{{k}_{1} sin α}{\sqrt{{k}_{0}^{2} + {k}_{1}^{2} - 2 {k}_{0} {k}_{1} cos α}} \qquad ( 16 )$$

The extension from such sinusoidal patterns to regularly spaced lines follow very similarly in the 1D case. From study of Fourier transform, we know that repetitive patterns of spatial period d corresponds to impulse trains at positive and negative integral multiple of spatial frequency

$$k = 2 π / d \qquad ( 17 )$$

This k is known in literature as the fundamental frequency of the repetitive pattern.

In other words, instead of two frequency component in each of FIGS. 3A and 3B, we would have infinite impulse trains in both: at integral multiples of ±k₀ along both sides of the kₓ axis in the former, and at integral multiple of ±k₁ distances along the line at angle α from the kₓ axis in the latter.

The superimposition of two such periodic patterns is the convolution of these two impulse trains, which includes impulses—at integral multiple of ±k₁ distances—along the lines intersecting at integral multiple of ±k₀ on the kₓ axis with angle α.

For simplicity, we shall call those frequency components—resulting from convolving two signals—which corresponds to the differences between the fundamental frequencies of the two convolving signals their first order differences. For example, the frequency components at (−k₀+k₁ cos α, k₁ sin α) and (k₀−k₁ cos α, −k₁ sin α) in FIG. 3(c) are the first order differences for the rotational mismatch of both the two sinusoidal pattern in 2D as well as the case of two sets of regularly spaced parallel lines.

In Section III.A.2, we will delve into the conditions under which the first order differences in the resulting convolution are the frequency components closest to the origin (i.e. the lowest frequencies in the higher dimensional spatial frequency space).

For the time being, let's suppose this is indeed the case, which means that the lowest frequency components as depicted in FIG. 3C continue to correspond to the resulting moire pattern. Substituting (17) into (15) and (16), we respectively have:

$$Δ {k}_{r} = \sqrt{{( \frac{2 π}{{d}_{0}} )}^{2} + {( \frac{2 π}{{d}_{1}} )}^{2} - 2 \frac{2 π}{{d}_{0}} \frac{2 π}{{d}_{1}} cos α} = \frac{2 π}{{d}_{0} {d}_{1}} \sqrt{{d}_{1}^{2} + {d}_{0}^{2} - 2 {d}_{0} {d}_{1} cos α}$$

$${δ}_{r} = π - arcsin \frac{\frac{2 π}{{d}_{1}} sin α}{\sqrt{{( \frac{2 π}{{d}_{0}} )}^{2} + {( \frac{2 π}{{d}_{1}} )}^{2} - 2 \frac{2 π2π}{{d}_{0} {d}_{1}} cos α}} = π - arcsin \frac{{d}_{0} sin α}{\sqrt{{d}_{1}^{2} + {d}_{0}^{2} - 2 {d}_{0} {d}_{1} cos α}}$$

We note that

$$Δ {k}_{r} = \frac{2 π}{Δ {d}_{r}}$$

where Δdᵣ is given in (8), and this δᵣ matches (12) exactly. In other words, the geometric analysis exactly matched the frequency domain analysis for moire patterns—resulting from rotational mismatch of extensions of 1D regularly spaced patterns into a 2^{nd} dimension.

### 4) Moire Pattern of Two Regular Rectangular Grids in Rotational Misalignment

A regular rectangular grid is formed by the superimposition of two sets of perpendicular regularly spaced parallel lines. This understanding leads to at least two different approaches to understanding the moire patterns they form.

One approach is to consider the moire patterns formed by their component regularly spaced parallel lines. Between two sets of such grids, there are four possible pairs of regularly spaced parallel lines forming moire patterns to consider. Since the amplification factor in moire effect is more pronounced when rotational misalignment is small, we may consider only the pairing with such small misalignment angles—which only takes place when the rectangular grids are slightly misaligned, and it leads to only two such pairings.

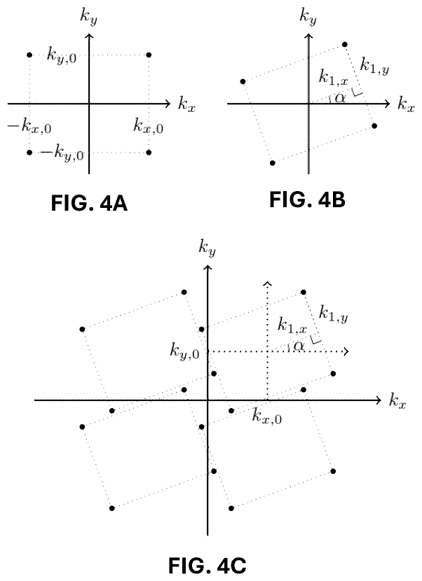

A second approach is to consider the representation of the rectangular grids as well as their moire pattern in the 2D Fourier domain. And we construct this understanding in the following. First, each rectangular grid is the result of superimposing two sets of regularly spaced parallel lines respectively with spacing dₓ and d_{y}, perpendicularly. As shown in FIGS. 4A and 4B, in the Fourier domain, the superimposition is a convolution of two sets of impulses—respectively at the integral multiple of their fundamental frequencies respectively at

$$\frac{2 π}{{d}_{x}} and \frac{2 π}{{d}_{y}} -$$

which are perpendicular with each other. More specifically, FIG. 4A is a representation of the dominant spatial frequencies of a 2D regular rectangular grid with

$${k}_{x , 0} = \frac{2 π}{{d}_{x , 0}} and {k}_{y , 0} = \frac{2 π}{{d}_{y , 0}} .$$

FIG. 4B is a representation of the dominant spatial frequencies of 2D regular rectangular grid with

$${k}_{x , 1} = \frac{2 π}{{d}_{x , 1}} and {k}_{y , 1} = \frac{2 π}{{d}_{y , 1}}$$

with rotation angle α. This results in frequency components at the intersection of a rectangular grid pattern with length and width equal to the two fundamental frequencies—excluding those on the kₓ and k_{y} axis.

Now, the rotation of such a rectangular grid would lead to corresponding rotation of these spatial frequencies. The superimposition of the two would lead to having their first order differences—which consist of four frequency components—as illustrated in FIG. 4C, which is a convolution of the two superimpositions corresponding to FIGS. 4A and 4B. And when these first order differences are the frequency components closest to the origin—a.k.a. they are the lowest frequency components—they correspond to the resulting moire pattern.

These two approaches lead to identical observations. Yet again the frequency domain analysis yields more direct insight. This is one perspective which we will rely on for building a few conceptual extensions—as presented in the next section.

### III. Conceptual Extensions

Classical moire patterns are the result of superimposition of 2 nearly identical regular patterns or even identical regular patterns in slight angular misalignment. While this might imply that the application of moire effects may also require the use of identical or near identical patterns, this is actually not true.

In this section, we expand the type of patterns which can be used to create moire effects. And the frequency domain analysis in the previous section turns out to offer much useful insight in the discussion.

### A. Using Periodic Patterns of Matching Periodicity

It turns out that a very broad class of periodic patterns with matching periodicity—instead of that particular pattern—can be used successfully in creating moire pattern with similar periodicity.

1) with a Pure Sinusoid

To illustrate this, we will consider the moire pattern resulting from superimposing a periodic on-off function—a square wave—with a pure sinusoid. And to develop this understanding, we start with the moire pattern of regularly spaced lines—in 1D.

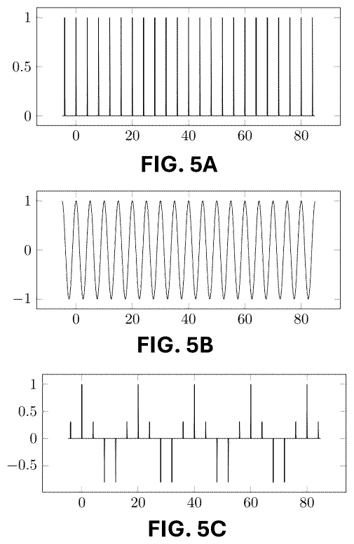

To closely simulate the 1D version of regularly spaced lines, we will let the duty-cycle of the on-off function to be infinitesimally small—in the limit, the square wave resembles an impulse train at regular interval d₀, as shown in FIG. 5A, where d₀=4.

We know from the analysis in the previous section that this impulse train, when superimposed with another impulse train at regular interval d₁—assuming their first order differences are the lowest frequencies in the result-would lead to a moire pattern with interval given by (4), which is

$$\frac{{d}_{0} {d}_{1}}{‖ {d}_{0} - {d}_{1} ‖} .$$

And the frequency domain analysis of this situation, as given in the previous section, is that the each of these impulse trains is represented by a Fourier series at integral multiple of their corresponding spatial frequencies respectively at

$${k}_{0} = 2 π / {d}_{0}$$

$${k}_{1} = 2 π / {d}_{1}$$

And their convolution led to the frequency components at their difference to be the lowest frequency components—i.e. closest to the origin—which is at:

$$‖ {k}_{0} - {k}_{1} ‖ = 2 π \vert \frac{1}{{d}_{0}} - \frac{1}{{d}_{1}} \vert = 2 π / \frac{{d}_{0} {d}_{1}}{‖ {d}_{0} - {d}_{1} ‖}$$

Now, suppose the second signal used in the convolution has all of its impulses at higher multiple of k₁ nullified—so that it only retains the two at ±k₁. The above argument clearly follows. In fact, the argument is simplified because only two copies (instead of infinite number of copies, one for each higher multiple of k₁) of the impulse trains for the first signal needs to be added together for the convolution, which guarantees their first order differences to be the lowest frequency components. The clipping of these impulses at higher multiples of k₁ leads to a pure sinusoid function, as shown in FIG. 5B. In FIG. 5B, k₁=d₁=5. FIG. 5C illustrates the resulting moire pattern, which shows the moire pattern with periodicity

$$Δ d = \frac{{d}_{0} {d}_{1}}{‖ {d}_{0} - {d}_{1} ‖} = 20 .$$

### 2) Moire Pattern and First Order Differences

From the above, we note that in general, moire patterns, if observed, correspond to the lowest frequency components of the superimposition—convolution in frequency domain—of the two signals or patterns. Moreover, we have so far focused on the cases when the first order differences of the dominant frequencies of the two convolving signals or patterns being the lowest frequency components in the resulting convolution. Naturally, there is a question of when such is the case—and we will attempt to shed some light on this question here.

First of all, we observe in Section III.A.1 that in 1D, convolving one infinite impulse train with a pure sinusoid—which includes two impulses at plus and minus of the sinusoid's frequency—led to the difference of their fundamental frequencies being the lowest frequency components. Visually, this remains the case for 2D (and even higher dimensional) patterns. The simplicity of this can be very attractive in practice as such sinusoidal patterns can be created simply using e.g. laser point sources and optical lenses.

Secondly, we note that the same can not be said for convolving two infinite 1D impulse trains in general. This is because the convolution places impulses at every

$$m {k}_{0} ( 0 ) + n {k}_{1} ( α )$$

for all integral m and n—meaning positive and negative integers and not 0—here, without the loss of generality, we use the first signal/pattern as the reference rotation angle θ, and place rotational mismatch, if any, entirely on the second signal, and we use the notation

$$k ( α ) = ( k cos α , k sin α )$$

as a shorthand to incorporate rotational angles as illustrated in FIG. 3(b). The condition that the first order differences being the lowest frequency components amounts to requiring

$$\vert {mk}_{0} ( 0 ) + n {k}_{1} ( α ) \vert >= max \vert {k}_{0} ( 0 ) - {k}_{1} ( α ) \vert , \vert - {k}_{0} ( 0 ) + {k}_{1} ( α ) \vert \qquad ( 18 )$$

$$∀ integral m , n when {mk}_{0} ( 0 ) + n {k}_{1} ( α ) \neq ( 0 , 0 )$$

(We exclude the combinations when mk₀(0)+nk₁(α)=(0, 0) from considerations because 0 frequency components correspond to a uniform constant background which does not interfere with the resulting moire pattern.) And we know that this is not true in general for all combination of k₀ and k₁.

Below, we will separately discuss the translational (α=0) and rotational (α≠0) moire effect cases.

For translational cases, that sum in (18) is reduced to a single dimension as in

$$m {k}_{0} ( 0 ) + n {k}_{1} ( 0 ) = ( m {k}_{0} + n {k}_{1} , 0 )$$

Here, we consider the class of infinite impulse trains with

$${d}_{0} = td \qquad ( 19 )$$

$${d}_{1} = ( t + 1 ) d$$

for some positive integral t and positive d, we can prove that the difference of their fundamental frequency is the lowest. Specifically,

$$m {k}_{0} + n {k}_{1} = 2 π ( \frac{m}{td} + \frac{n}{( t + 1 ) d} ) = 2 π \frac{m ( t + 1 ) d + n d}{t ( t + 1 ) {d}^{2}} = \frac{2 π}{t ( t + 1 ) {d}^{2}} \times ( ( m + n ) t + m ) = \frac{2 π}{Δ d} \times ( ( m + n ) t + m )$$

where we used (4) for the last equality. Now, we observe that (m+n)t+m must be integral. In other words, they may contribute to the lowest frequency components (which corresponds to the resulting moire pattern) or the 0 frequency component (which corresponds to a uniform constant background and does not contribute any patterns). This satisfies (18).

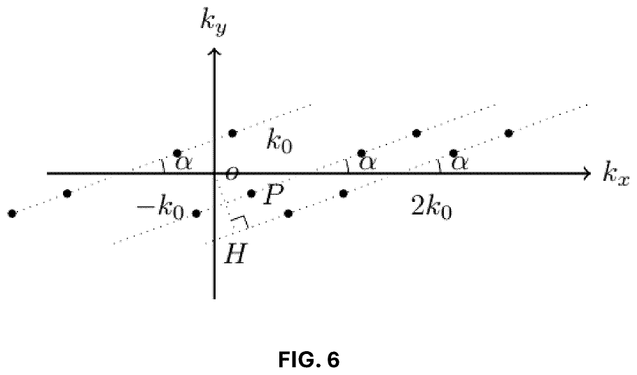

There may be other such classes, but the above class is generally quite practicable in real applications. The rotation cases have at least one class satisfying (18) with simple geometric visualization. FIG. 6 illustrates the convolution results of two such impulse trains—respectively with fundamental spatial frequencies k₀ and k₁—at rotational mismatch angle of α, where α≠0° and α≠90°. As illustrated in the figure, this convolution led to the duplication of the set of impulse trains of k₁ at angle α to the kₓ axis, at each integral multiple of k₀.

For ease of discussion, we shall use the term m^{th} order spectral line to refer to the line which contains all of the duplicates of the impulse trains of k₁ at mk₀. Note that all these spectral lines are in parallel.

Let P denote the frequency component k₀(0)−k₁(α). P is on the 1^{st} order spectral line. And let H be the perpendicular intersection of line from origin to the 2^{nd} order spectral line, we know that the line from origin to H is also perpendicular to all of the other spectral lines because they are all in parallel.

Note that that should the distance from origin to H be no smaller than the distance from the origin to P, then the point P must be closer to the origin than any points on that spectral line passing H; and consequently P must be closer to the origin than any points on any higher positive order spectral lines associated with. Noting that the distance from the origin to H is 2k₀ sin α, we have the following sufficient condition for P to be the lowest frequency components amongst all positive order spectral lines:

$$2 {k}_{0} sin α \geq \vert {k}_{0} ( 0 ) - {k}_{1} ( α ) \vert = \sqrt{{( {k}_{0} - {k}_{1} cos α )}^{2} + {( {k}_{1} sin α )}^{2}} = \sqrt{{k}_{0}^{2} + {k}_{1}^{2} - 2 {k}_{0} {k}_{1} cos α}$$

Square both sides, divide both sides by k₀², we have

$$2 sin α \geq 1 + {( \frac{{k}_{1}}{{k}_{0}} )}^{2} - 2 ( \frac{{k}_{1}}{{k}_{0}} ) cos α \qquad ( 20 )$$

To understand the implication of this inequality, we first consider the case when P is on the line from origin to H, i.e. k₁=k₀ cos α. Plug this into the inequality, we have:

$$2 sin α \geq 1 + cos {α}^{2} - 2 cos α cos α = sin {α}^{2}$$

which is true for all sin α≥0 as the magnitude of sine function is no greater than 1. Intuitively this makes sense.

The second case we consider is when k₀=k₁. Plug into (20), we have:

$$2 sin α \geq 1 + 1 - 2 cos α = 2 - 2 cos α$$

Divide both sides by 2, and collecting all terms with a to the same side, we have

$$sin α + cos α \geq 1$$

Applying sum angle formula to the left hand side, we have

$$\sqrt{2} sin ( α + π / 4 ) \geq 1$$

which is always true for α∈[0,π/2].

Using these two cases, it's easy to see, geometrically, that k₁ ∈[k₀ cos α, k₀] should also satisfy (20). Using symmetry around the line from the origin to H, we also have k₁ ∈[k₀, k₀/cos α] satisfying (20). Combine the two, we have:

$${k}_{1} ∈ [ {k}_{0} cos α , {k}_{0} / cos α ] \qquad ( 21 )$$

Whereas (20) is more general, (21) provides more immediate insight for a more restrictive class of cases.

In the above, we presented three classes of cases when the moire pattern corresponds to the first order differences of the fundamental frequencies from the two component signals or patterns. These conditions, while not exhaustive, provide for a broad class of applications in practice.

### B. Moire Patterns in Noise

The preceding analysis is based on pure signals and patterns, and does not include any consideration of any practical measurement and/or observational noise. The proper application of all of the above in practice needs to take into account these extra frequency components—all around the spectrum, and in random and unpredictable amounts.

In standard signal processing practice and understanding, appropriate application of such idealized or theoretical understanding in practice depends on having appropriate levels of signal-to-noise ratio (SNR). This is so that the resulting effect from the theoretical analysis is strong enough to rise above the level of noise in the resulting signals (and patterns)—to be detectable and measurable. And mechanisms which enhance the SNR in results—called filtering—continue to be a focus of the signal processing field today.

These signal processing practices and understandings clearly can be applied here. Specifically, we expect that appropriate level of SNR—of the regular pattern vs. noise—could help to make the moire effect detectable and measurable; and filtering out unwanted or unrelated frequency components occupied by noise could help to boost SNR of desired moire patterns.

As it turns out, both of these can have far greater significance and applicability to moire effect than just that.

Recall our earlier discussion on conditions ensuring the first order differences to be the lowest frequency components, we may extend the understanding of SNR to consider instead ensuring the first order differences be appropriately pronounced over the other frequency components (resulting from the convolution) and noise—this is analogous to the signal processing usage of signal-to-interference ration (SIR).

With this in mind, we can similarly extend the practice and understanding in managing interference and noise to boost the SIR of the resulting moire pattern. These include:
Method 1: choose base signals with appropriately attenuated and or nullified components at higher multiples-both positive and negative—of their fundamental frequencies
Method 2: choose base signals to enhance the desired moire pattern
Method 3: use filters to degrade or even nullify the frequency components of the two base patterns at higher multiples-both positive and negative—of their fundamental frequencies
Method 4: use filters to specifically degrade or even nullify those undesirable frequency components interfering with the desired moire pattern.

In some applications—e.g. alignment and metrology in chip fabrication—moire effect is used to make measurements of one base pattern using another. For simplicity, we will call the former the target base signal or target base pattern, or simply target signal or target pattern for brevity; and call the latter reference base signal or reference base pattern, or simply reference signal or reference pattern for brevity.

In these applications, we often do not have much control over the target pattern. The above analysis and understanding supports choosing reference patterns to enable or enhance particular desired resulting moire pattern. One example is when the target pattern contains frequency components—in addition to the fundamental frequency of interest—we may design the reference pattern to have negative magnitudes at higher multiple of its fundamental frequency for the purpose of reducing or even nullifying some of these additional frequency components around the first order differences. Analysis in the frequency domain can be a great tool to visualize and design in such endeavors.

Finally, we note that the preceding discussions are all focused on having the first order differences of the base patterns as the desired resulting moire pattern. We observe that this needs not be the case—indeed it is entirely perceivable that some higher order differences—or the combination of a number of different such differences—are the observed or even desired moire pattern. We note that the frequency and geometric analysis employed in the above can also be used in analyzing these situations, and similar techniques as presented in the above can be used for creating, enhancing, and even diminishing the desired moire results.

### C. Incomplete Patterns

So far, the discussion of moire effects have been based on two complete base patterns-meaning that within the extend of some duration or space for observing the resulting moire pattern, both underlying base patterns cover the full duration or space and are completely regular. Whereas moire patterns of incomplete base patterns are often observed, the application of moire effects—where moire patterns are detected and measured and/or used for deducing some additional characteristic of the base patterns (such as used in alignment and metrology of chip fabrication)—have mostly limited to the use of complete base patterns.

In the following, we extend the understanding presented in the above to incomplete base patterns. In the process, we will combine the Fourier analysis with noisy environment understanding presented in the above. And we will show that this combination of perspectives provides insights into the application of moire effects resulting from incomplete base patterns.

One approach to consider incomplete base patterns is as the superimposition of a mask over a complete pattern—where the mask takes on the value of 1 where the pattern is present, and 0 where the pattern is absent (or masked off).

We observe that if the mask has features no smaller than the spacing of the complete (regular) pattern, its Fourier transform is analogous to a baseband signal—meaning centered around the origin—with a bandwidth smaller than the dominant frequency of the regular pattern.

The superimposition of such a mask onto the regular pattern translates to a convolution of the mask's Fourier transform with the regular pattern's Fourier transform. This adds the mask's Fourier transform at each of the regular pattern's impulse—with the weight of that impulse.

Now consider using a pure sinusoidal based pattern—of some chosen spatial frequencies—as a reference pattern for creating moire pattern with this incomplete pattern as the target pattern.

Again interpreting their superimposition as convolution in the Fourier domain, we observe that it results in the replication of the mask's Fourier transform at each of the m^{th} order difference of the regular pattern's frequencies with the plus and minus frequency of the pure sinusoid.

In particular, we observe that the lowest groups of frequency components of the result are the replication of the mask's Fourier transform centered at the first order differences of the regular target pattern and the sinusoidal reference pattern.

In other words, the result may be a bit messy—as it contains all frequency components of the mask—but the concept of lowest frequency components, which corresponded to moire patterns in the analysis of complete base patterns, is preserved in these lowest frequency groups.

The complication here is that the baseband mask signal can be pretty broad, and the replication of this baseband signal at multiple frequency components—in the convolution—may lead to overlapping of frequency components—an effect called frequency aliasing or simply aliasing in signal processing jargon. On the other hand, since the objective here is not to reconstruct the mask pattern, we are actually not concerned about the aliasing per se. What we are interested in is some desirable resulting moire pattern—some repetitive patterns significant enough to be detected and measured for some engineering purpose.

Consider the case where the desired moire pattern is as before, which is the first order differences between the complete target pattern with the reference pattern. In other words, we are only interested in preserving that frequency component of the incomplete target pattern at the fundamental frequency of its component complete grid pattern. Retracing the construction of the incomplete pattern through the superimposition of the mask signal, we note that it is multiplied by the 0 frequency (or DC) component of the mask pattern. Assuming the DC component of the mask signal is not 0, we can proceed to construct filters to either pre-filter the target pattern, meaning before superimposition with any reference patterns and/or post-filter, meaning after the superimposition. The pre-filter can either extract only the fundamental frequency component of the target pattern or aim to nullify any undesirable contribution at the first order difference frequencies. The latter can then be combined with a post-filter to isolate the desired results.

In cases when the SIR of the target pattern—specifically the magnitude of the fundamental frequency for the complete target pattern over the peak magnitude of the mask pattern and/or the combined signal energy of the mask pattern (over all of its frequencies)—is appropriately large, then we may follow the reasoning in the previous section and conclude that the filtering may not even be necessary for the purpose of detecting and measuring the resulting moire effect. Note that this corresponds to having significant portion of the complete target pattern be preserved through the mask superimposition. Also observe that filtering to constrain peak frequency components of the mask signal and/or the overall bandwidth of the mask signal can be used to enhance this SIR as well—and this can be accomplished with both pre- and post-filtering or both.

Here again, we note that suitable design of the reference pattern can aid the creation and enhancement of desired moire results. And we again note the visual insight frequency domain analysis can offer here, also toward any other type of moire patterns from incomplete target patterns.

### IV. Application to Chip Mask Alignment and Metrology

Microchips are fabricated by successively placing different material layers on top of each other. To ensure the proper function of micro devices created at the intersection of different material layers, different material layers need to be placed at precise relative location-within some engineering tolerances—to each other. Because the thickness of each such layer is very small compared to the dimensions of a microchip, this precision placement problem is often considered in the 2D plane, which comprises of translation and rotation measurements and adjustments. The measurement is part of a suite of metrological tools to inspect and test the fabrication equipment, process, and resulting chip. And the combined measurement and adjustment leading up to and during the lithography process (for placing additional layers of material) is often referred to as alignment.

The increase in the density of micro devices—which was stipulated to follow Moore's law over the years—requires corresponding decrease in the dimension of the material strips which collectively create these micro devices. The engineering tolerance for alignment is often no more than ⅓ of the dimension of the material strip. As an example, the alignment requirement for a 3 nm material strip is no greater than 1 nm.

In common optical understanding, feature smaller than ½ wavelength diffracts—instead of reflects—most of the light's energy. This is one direct reason why, over the years, lithographic processes using shorter and shorter wavelength light needed to be developed to support the increase in micro device density.

For comparison, the shortest wavelength of visible light is around 380 nm. Currently, most chip fabrication uses deep ultraviolet (DUV) spectrum light between 150 nm and 300 nm wavelength, most frequently 248 nm (with krypton fluoride (KrF) laser) and 193 nm (with argon fluoride (ArF) laser). The next generation lithographic process proposes to use extreme ultraviolet (EUV) light at 13.5 nm wavelength. And creative use of a technique called structured illumination is employed in combination with the shorter wavelength laser to achieve lithography of material strip dimension down to single digits of nm.

To control the cost of lithographic equipment, and to avoid using the same wavelength of light used for lithography (so that the photosensitive material is not exposed before lithography), it is highly desirable for the alignment process to use light with greater wavelength. Amplifying feature dimension so that detection and measurements can be done at coarser scale- and using light with longer wavelength is where the moire effect can really shine.

In the rest of this section, we will introduce a set of techniques which uses the pattern of the previous chip material layers for alignment. This approach alleviates the need of specially designed patterns dedicated for alignment purposes, and promises to avail more space for micro devices and support finer detection, measurement, and adjustments for alignments.

We start with proposing a moire effect based mechanism for detecting and measuring translational mis-alignments.

### A. Boundary Moire Effect

1) Base Setup with 1D Signals

For ease of analysis, we start with the 1D signal case. Let the target signal x(t) be the composite of two sinusoids with frequencies f₀ and f₁ connected at some St. Specifically:

$$x ( t ) = \{ \text{} \begin{matrix}cos ( 2 π {f}_{0} ( t - δ t ) ) & t < δ t \\ cos ( 2 π {f}_{1} ( t - δ t ) ) & t \geq δ t\end{matrix} \text{} \qquad ( 22 )$$

Now, consider using a pure sinusoid of frequency fᵣ as the reference signal r(t), i.e.

$$r ( t ) = cos ( 2 π {f}_{r} t ) \qquad ( 23 )$$

The objective is to use this reference to create moire effects with x(t) for the purpose of detecting and measuring δt—with the moire effect helping in amplifying the effect of δt to larger scale.

### 2) Analysis

Let's see what happens when we superimpose the two.

$$x ( t ) \times r ( t ) = \{ \text{} \begin{matrix}cos ( 2 π {f}_{0} ( t - δ t ) ) cos ( 2 π {f}_{r} t ) & t < δ t \\ cos ( 2 π {f}_{1} ( t - δ t ) ) cos ( 2 π {f}_{r} t ) & t \geq δ t\end{matrix} =$$

$$\{ \begin{matrix}\begin{matrix}\frac{1}{2} cos ( 2 π ( {f}_{0} + {f}_{r} ) t - 2 π {f}_{0} δ t ) + \\ \frac{1}{2} cos ( 2 π Δ {f}_{0} t - 2 π {f}_{0} δ t )\end{matrix} & t < δ t \\ \begin{matrix}\frac{1}{2} cos ( 2 π ( {f}_{1} + {f}_{r} ) t - 2 π {f}_{1} δ t ) + \\ \frac{1}{2} cos ( 2 π Δ {f}_{1} t - 2 π {f}_{1} δ t )\end{matrix} & t \geq δ t\end{matrix} \text{}$$

$$where$$

$$Δ {f}_{0} = {f}_{0} - {f}_{r} \qquad ( 24 )$$

$$Δ {f}_{1} = {f}_{1} - {f}_{r} \qquad ( 25 )$$

As in the analysis of classic moire effects in the above, we focus on the second term in both cases for the resulting moire effect.

We note that across δt, there is a change in the spacing between the moire pattern. From the above, we know that on the left side, the spacing between the peaks is 1/Δf₀, while it is 1/Δf₁ on the right. Across this boundary, the distances between the two immediate peaks can vary depending on δt—and this is what we will focus on below.

Note that the peak value of these second terms are attained when the phase of the cosine functions are at integral multiple of 2π and 0. We may then solve for the time instants for these peaks and obtain the following, for integral i and j:

$${T}_{0} ( i ) = \frac{2 i π + 2 π {f}_{0} δ t}{2 π Δ {f}_{0}} = \frac{i + {f}_{0} δ t}{Δ {f}_{0}} = \frac{i + {f}_{r} δ t}{Δ {f}_{0}} + δ t {T}_{0} ( i ) < δ t \qquad ( 26 )$$

$${T}_{1} ( j ) = \frac{2 j π + 2 π {f}_{1} δ t}{2 π Δ {f}_{1}} = \frac{j + {f}_{1} δ t}{Δ {f}_{1}} = \frac{j + {f}_{r} δ t}{Δ {f}_{1}} + δ t {T}_{1} ( j ) \geq δ t \qquad ( 27 )$$

Substituting T₀(i) and T₁(j) respectively into their conditions, after some algebraic manipulation, we have the following:

$$i ≶ - {f}_{r} δ t Δ {f}_{0} ≷ 0 \qquad ( 28 )$$

$$j ⋛ - {f}_{r} δ t Δ {f}_{1} ⋛ 0 \qquad ( 29 )$$

Note that should fᵣδt contain any integral parts, it is equivalent to shifting r(t) by that many integral multiple of periods of the sinusoid in r(t), which is 1/fᵣ. In other words, the resulting moire pattern repeats itself over 1/fᵣ, therefore is limited to resolving δt within 1/fᵣ. We therefore will only consider cases when

$$δ t ∈ ( 0 , \frac{1}{{f}_{r}} ) \qquad ( 30 )$$

Accordingly, across this boundary δt, the i and j values start at 0 or −1. Let i₀ and j₀ respectively denote their starting values, and let ΔT=T₁(j₀)−T₀(i₀) denote the desired difference across the boundary. We analyze ΔT for each of the four cases below.

$$\begin{matrix}Case 1 & \\ {f}_{1} < {f}_{r} < {f}_{0} & ( 31 )\end{matrix}$$

$$Δ T = {T}_{1} ( {j}_{0} ) - {T}_{0} ( {i}_{0} ) = {T}_{1} ( - 1 ) - {T}_{0} ( - 1 ) = \frac{- 1 + {f}_{r} δ t}{Δ {f}_{1}} - \frac{- 1 + {f}_{r} δ t}{Δ {f}_{0}} = ( \frac{1}{Δ {f}_{0}} + \frac{1}{- Δ {f}_{1}} ) ( 1 - {f}_{r} δ t )$$

Note that as fᵣδt varies from 0 to 1, ΔT decreases from 1/Δf₀+1/−Δf₁ to 0.

$$\begin{matrix}Case 2 & \\ {f}_{0} < {f}_{r} < {f}_{1} & ( 32 )\end{matrix}$$

$$Δ T = {T}_{1} ( {j}_{0} ) - {T}_{0} ( {i}_{0} ) = {T}_{1} ( 0 ) - {T}_{0} ( 0 ) = \frac{{f}_{r} δ t}{Δ {f}_{1}} - \frac{{f}_{r} δ t}{Δ {f}_{0}} = ( \frac{1}{Δ {f}_{1}} + \frac{1}{- Δ {f}_{0}} ) {f}_{r} δ t$$

Note that as fᵣδt varies from 0 to 1, ΔT increases from 0 to 1/Δf₁+1/−Δf₀.

$$\begin{matrix}Case 3 & \\ {f}_{r} < {f}_{0} , {f}_{1} & ( 33 )\end{matrix}$$

$$Δ T = {T}_{1} ( {j}_{0} ) - {T}_{0} ( {i}_{0} ) = {T}_{1} ( 0 ) - {T}_{0} ( - 1 ) = \frac{{f}_{r} δ t}{Δ {f}_{1}} - \frac{- 1 + {f}_{r} δ t}{Δ {f}_{0}} = \frac{1}{Δ {f}_{0}} + ( \frac{1}{Δ {f}_{1}} - \frac{1}{Δ {f}_{0}} ) {f}_{r} δ t$$

Note that as fᵣδt varies from 0 to 1, ΔT increases from 1/Δf₀ to 1/Δf₁.

$$\begin{matrix}Case 4. & \\ {f}_{0} , {f}_{1} < {f}_{r} & ( 34 )\end{matrix}$$

$$Δ T = {T}_{1} ( {j}_{0} ) - {T}_{0} ( {i}_{0} ) = {T}_{1} ( - 1 ) - {T}_{0} ( 0 ) = \frac{- 1 + {f}_{r} δ t}{Δ {f}_{1}} - \frac{{f}_{r} δ t}{Δ {f}_{0}} = \frac{1}{- Δ {f}_{1}} + ( \frac{1}{- Δ {f}_{0}} - \frac{1}{- Δ {f}_{1}} ) {f}_{r} δ t$$

Note that as fᵣδt varies from 0 to 1, ΔT increases from 1/−Δf₁ to 1/−Δf₀.

In the analysis of these cases, we kept the minus signs with Δf's wherever appropriate to maintain the positivity of the resulting terms. And this helped to reveal similarities between the cases. Specifically, the multiplicative factor to fᵣδt is the sum of the moire effect spacing on the two sides of the boundary in the first two cases, and is the difference for the last two cases.

We note that the first two cases are simply swapping the two frequency components in x(t), and observe that as δt increases from 0 to 1/fᵣ, the resulting ΔT spans from 0 to the sum of the two moire effect spacing. For the last two cases, their ΔT linearly changes from the regular spacing of the moire effect from one side of the boundary to the other with the rate fᵣδt.

This comparison leads to the conclusion that the range of ΔT is greater in the first two cases than the last two, which makes the former possibly more useful in providing greater resolution for δt in practice.

In all cases, we note that the resulting, AT, is related with the offset δt by a multiple of fᵣ over some frequency difference. Notably, this amplification factor is not as great as the classic moire effect as given in (3), at 1 over the frequency difference. We will develop additional mechanisms to address this lack of amplification later in this section.

From the first two cases, we note that for fixed differences between f₀ and f₁, choosing fᵣ to be their average minimizes the multiplicative factor at

$$4 / \vert {f}_{0} - {f}_{1} \vert = 2 / \vert Δ {f}_{0} \vert = 2 / \vert Δ {f}_{1} \vert$$

Skewing fᵣ toward either f₀ of f₁ can increase this factor considerably. This is because the spacing of moire effect on either side grows inversely proportional to their frequency difference. Similar effect takes place with the last two cases as well.

Note that we may similarly extend this technique to regular but not identical signals for x(t) and r(t)—and in this case we may even choose different regular signals on the two sides of x(t)—as well as extending the 1D signal to 2D patterns and grids.

### 3) Extension to Incomplete Signals

Recall, in the discussion of classic moire effects, the extension of moire effect into incomplete patterns and signals was possible because the repetition of the resulting moire pattern allows for some missing or masked out sections. The boundary effect described here is based on the distance from the first peak on both sides of the boundary, which, on initial impression, may not appear to be able to withstand the loss of either of these first peaks. While it is certainly true that there are situations when measuring the spacing between these first peaks ΔT becomes impossible, there turns out to be a number of approaches to overcome this issue.

The first approach is from the observation that varying the reference signal's phase angle over its period 1/fᵣ results in spanning ΔT over its entire range. This is not surprising by the periodicity of the reference signal. However, as the target signal is not fully periodic, it is worthwhile to develop this formally below.

Consider extending the reference signal used in the above r(t) by introducing a variable offset δt. Specifically, let

$$r ( δ τ , t ) = cos ( 2 π {f}_{r} ( t - δ τ ) ) \qquad ( 35 )$$

The superimposition of r(δτ,t) and x(t) is given by

$$x ( t ) \times r ( δ τ , t ) == \{ \text{} \begin{matrix}cos ( 2 π {f}_{0} ( t - δ t ) ) cos ( 2 π {f}_{r} ( t - δ τ ) ) & t < δ t \\ cos ( 2 π {f}_{1} ( t - δ t ) ) cos ( 2 π {f}_{r} ( t - δ τ ) ) & t \geq δ t\end{matrix} \text{} =$$

$$\{ \text{} \begin{matrix}\begin{matrix}\frac{1}{2} cos ( 2 π ( {f}_{0} + {f}_{r} ) t - 2 π ( {f}_{0} δ t + {f}_{r} δ τ ) ) + \\ \frac{1}{2} cos ( 2 πΔ {f}_{0} t - 2 π ( {f}_{0} δ t - {f}_{r} δ τ ) )\end{matrix} & t < δ t \\ \begin{matrix}\frac{1}{2} cos ( 2 π ( {f}_{1} + {f}_{r} ) t - 2 π ( {f}_{1} δ t + {f}_{r} δ τ ) ) + \\ \frac{1}{2} cos ( 2 πΔ {f}_{1} t - 2 π ( {f}_{1} δ t - {f}_{r} δ τ ) )\end{matrix} & t \geq δ t\end{matrix} \text{}$$

We may then similarly extend T₀(i) and T₁(j) to the following:

$${T}_{0} ( δ τ , i ) = \frac{2 i π + 2 π ( {f}_{0} δ t - {f}_{r} δ τ )}{2 π Δ {f}_{0}} = \frac{i + {f}_{r} ( δ t - δ τ )}{Δ {f}_{0}} + δ t \qquad ( 36 )$$

$${T}_{1} ( δ τ , j ) = \frac{2 j π + 2 π ( {f}_{1} δ t - {f}_{r} δ τ )}{2 π Δ {f}_{1}} = \frac{j + {f}_{r} ( δ t - δ τ )}{Δ {f}_{1}} + δ t \qquad ( 37 )$$

$$And :$$

$$i ≶ - {f}_{r} ( δ t - δ τ ) Δ {f}_{0} ≷ 0 \qquad ( 38 )$$

$$j ⋛ - {f}_{r} ( δ t - δ τ ) Δ {f}_{1} ⋛ 0 \qquad ( 39 )$$

We again note that the periodicity of the reference and target signal creates dependency of the integral values i and j on δt−δτ relative to 1/fᵣ.

We similarly define ΔT(δt) as the spacing between the first peak from the two sides of the boundary, the case for δt−δτ>0 directly follows from the 4 cases discussed previously. For easy of comparison, we copy the results here:

$$Δ T ( δ τ ) == \qquad ( 40 )$$

$$\{ \text{} \begin{matrix}( \frac{1}{Δ {f}_{0}} + \frac{1}{0.75 [ 1. ] - Δ {f}_{1}} ) ( 1 - {f}_{r} ( δ t - δ τ ) ) & {f}_{1} < {f}_{r} < {f}_{0} \\ ( \frac{1}{Δ {f}_{1}} + \frac{1}{0.75 [ 1. ] - Δ {f}_{0}} ) {f}_{r} ( δ t - δ τ ) & {f}_{0} < {f}_{r} < {f}_{1} \\ \frac{1}{Δ {f}_{0}} + ( \frac{1}{Δ {f}_{1}} - \frac{1}{Δ {f}_{0}} ) {f}_{r} ( δ t - δ τ ) & {f}_{r} < {f}_{0} , {f}_{1} \\ \begin{matrix}\frac{1}{0.75 [ 1. ] - Δ {f}_{1}} + ( \frac{1}{0.75 [ 1. ] - Δ {f}_{0}} - \frac{1}{0.75 [ 1. ] - Δ {f}_{1}} ) \\ {f}_{r} ( δ t - δ τ )\end{matrix} & {f}_{r} > {f}_{0} , {f}_{1}\end{matrix} \text{}$$

For δt−δτ<0, we have the following:

$$i ≶ - {f}_{r} ( δ τ - δ t ) Δ {f}_{0} ≷ 0 \qquad ( 41 )$$

$$j ⋛ - {f}_{r} ( δ τ - δ t ) Δ {f}_{1} ⋛ 0 \qquad ( 42 )$$

$$Δ T ( δ τ ) == \qquad ( 43 )$$

$$\{ \text{} \begin{matrix}( \frac{1}{0.75 [ 1. ] - Δ {f}_{1}} + \frac{1}{Δ {f}_{0}} ) {f}_{r} ( δ τ - δ t ) & {f}_{1} < {f}_{r} < {f}_{0} \\ ( \frac{1}{Δ {f}_{1}} + \frac{1}{0.75 [ 1. ] - Δ {f}_{0}} ) ( 1 - {f}_{r} ( δ τ - δ t ) & {f}_{0} < {f}_{r} < {f}_{1} \\ \frac{1}{Δ {f}_{1}} + ( \frac{1}{Δ {f}_{0}} - \frac{1}{Δ {f}_{1}} ) {f}_{r} ( δ τ - δ t ) & {f}_{r} < {f}_{0} , {f}_{1} \\ \begin{matrix}\frac{1}{0.75 [ 1. ] - Δ {f}_{0}} + ( \frac{1}{0.75 [ 1. ] - Δ {f}_{1}} - \frac{1}{0.75 [ 1. ] - Δ {f}_{0}} ) \\ {f}_{r} ( δ τ - δ t )\end{matrix} & {f}_{r} > {f}_{0} , {f}_{1}\end{matrix} \text{}$$

We switched order of δτ and δt keep their difference term positive, and we similarly added minus signs to Δf's when appropriate to also maintain their positivity.

Noting that the transition at δt−δt=0 for each case is smooth and continuous, this derivation is complete.

A direct application of this understanding to incomplete signal pattern is that we are not dependent on being able to observe the first peaks at a one particular offset δτ. In most applications where we have control over the reference signal, it is possible to adjust the reference signal's phase angle- and doing so is often fairly simple and straightforward. In such cases, we may sample across 2π phase variation-which is equivalent to spacing of 1/fᵣ—starting from any arbitrarily chosen relative offset to the target, and look for when the first peaks on both sides of the boundary appear. In other words, it would require the first peaks to be completely missing—caused by incomplete signal pattern-over the entire span of 1/fᵣ in order to completely obscure the boundary effect.

But observing the first peaks on both sides of the boundary is not all that we can do. Recall that the peaks resulting from moire effect on both sides of the boundaries have regular spacing, respectively at 1/|Δf₀| and 1/|Δf₁|. And since the boundary resides within the only span—as denoted by two adjacent peaks—with a varying spacing with δτ, it is indeed not difficult to identify its proximity to within the smaller of 1/|Δf₀| and 1/|Δf₁|, just by observing drifting of all of the peaks in the resulting moire effect while varying δτ. Since the spacing on both sides of the boundary are regular and known, it is a straightforward exercise of integral counting to insert the missing peaks on either side. We may then use the spacing between any two observable peaks across the boundary to estimate ΔT (δt) for that δτ using this equation:

$$Δ {T}_{m , n} ( δ τ ) = \frac{m - 1}{\vert Δ {f}_{0} \vert} + Δ T ( δ τ ) + \frac{n - 1}{\vert Δ {f}_{1} \vert} \qquad ( 44 )$$

where m and n respectively denote the number of peaks to the left and right of the boundary between which the spacing measurement is made.

This allows bits and pieces of the resulting pattern-spreading over the entire span of the target and reference signals—to be used for measuring the boundary effect to overcome the incompleteness of the target signal patterns.

Clearly, 2D patterns offer even more such bits and pieces and hence more immunity to incompleteness.

Finally, we note that multiple ΔT_{m,n}(δt) for distinct pairs of m and n can be used to give independent estimates of St, which can then be combined to arrive at higher quality joint estimates. And this is useful for both complete and incomplete signal patterns.

4) Extension to Boundary with a Gap

In this part, we consider yet another extension for target signal containing a gap over the boundary. Specifically,

$$x ( t ) = \{ \text{} \begin{matrix}cos ( 2 π {f}_{0} ( t - δ t ) ) & t < δ t \\ 0 & δ t \leq t < δ t + δ g \\ cos ( 2 π {f}_{1} ( t - ( δ t + δ g ) ) ) & t \geq δ t + δ g\end{matrix} \text{} \qquad ( 45 )$$

Using the same r(δτ,t) as in (35), we have the following superimposition:

$$x ( t ) \times r ( t ) = \{ \text{} \begin{matrix}cos ( 2 π {f}_{0} ( t - δ t ) ) cos ( 2 π {f}_{r} ( t - δ τ ) ) \\ 0 \\ cos ( 2 π {f}_{1} ( t - ( δ t + δ g ) ) ) cos ( 2 π {f}_{r} ( t - δ τ ) )\end{matrix} \text{} =$$

$$\{ \text{} \begin{matrix}\begin{matrix}\frac{1}{2} cos ( 2 π ( {f}_{0} + {f}_{r} ) t - 2 π ( {f}_{0} δ t + {f}_{r} δ τ ) ) + \\ \frac{1}{2} cos ( 2 πΔ {f}_{0} t - 2 π ( {f}_{0} δ t + {f}_{r} δ τ ) )\end{matrix} & t < δ t \\ 0 & δ t \leq t < δ t + δ g \\ \begin{matrix}\frac{1}{2} cos ( 2 π ( {f}_{1} + {f}_{r} ) t - 2 π ( {f}_{1} ( δ t + δ g ) + {f}_{r} δ τ ) ) + \\ \frac{1}{2} cos ( 2 πΔ {f}_{1} t - 2 π ( {f}_{1} ( δ t + δ g ) - {f}_{r} δ τ ) )\end{matrix} & t \geq δ t + δ g\end{matrix} \text{}$$

Following similar development as in Section IV.A.2, we have the following:

$${T}_{0} ( i ) = \frac{2 i π + 2 π ( {f}_{0} δ t - {f}_{r} δ τ )}{2 π Δ {f}_{0}} = \frac{i + {f}_{r} ( δ t - δ τ )}{Δ {f}_{0}} + δ t \qquad ( 46 )$$

$${T}_{1} ( j ) = \frac{2 j π + 2 π ( {f}_{1} ( δ t + δ g ) - {f}_{r} δ τ )}{2 π Δ {f}_{1}} = \frac{j + {f}_{r} ( δ t + δ g - δ τ )}{Δ {f}_{1}} + δ t + δ g \qquad ( 47 )$$

$$and$$

$$i ≶ - {f}_{r} ( δ t - δ τ ) Δ {f}_{0} ≷ 0 \qquad ( 48 )$$

$$j ⋛ - {f}_{r} ( δ t + δ g - δ τ ) Δ {f}_{1} ⋛ 0 \qquad ( 49 )$$

Again noting the shared dependency of i and j on the integral part of fᵣ St, we let └x┘ and ┌x┐ respectively denote the greatest integer less than or smallest integer greater than x, and have the following:

$$Δ T ( δ τ ) = δ g - ( \frac{- {f}_{r} ( δ t + δ g - δ τ )}{Δ {f}_{1}} - \frac{- {f}_{r} ( δ t - δ τ )}{Δ {f}_{0}} ) ++ \qquad ( 50 )$$

$$\{ \text{} \begin{matrix}\frac{⌊ - {f}_{r} ( δ t + δ g - δ τ ) ⌋}{Δ {f}_{1}} - \frac{⌊ - {f}_{r} ( δ t - δ τ ) ⌋}{Δ {f}_{0}} & {f}_{1} < {f}_{r} < {f}_{0} \\ \frac{⌈ - {f}_{r} ( δ t + δ g - δ τ ) ⌉}{Δ {f}_{1}} - \frac{⌈ - {f}_{r} ( δ t - δ τ ) ⌉}{Δ {f}_{0}} & {f}_{0} < {f}_{r} < {f}_{1} \\ \frac{⌈ - {f}_{r} ( δ t + δ g - δ τ ) ⌉}{Δ {f}_{1}} - \frac{⌊ - {f}_{r} ( δ t - δ τ ) ⌋}{Δ {f}_{0}} & {f}_{r} < {f}_{0} , {f}_{1} \\ \frac{⌊ - {f}_{r} ( δ t + δ g - δ τ ) ⌋}{Δ {f}_{1}} - \frac{⌈ - {f}_{r} ( δ t - δ τ ) ⌉}{Δ {f}_{0}} & {f}_{r} > {f}_{0} , {f}_{1}\end{matrix} \text{}$$

We purposefully rewrite the numerator terms on top of 1/Δf's to match those in the cases to highlight that it is the difference with their corresponding integral counter parts which contributes to this ΔT (δt) spacing.

Note that the δg is preserved in the resulting spacing, as expected.

We note in particular, that when fᵣ(δt−δτ) is an integer,

$$- {f}_{r} ( δ t - δ {τ}_{0} ) = ⌊ - {f}_{r} ( δ t - δ {τ}_{0} ) ⌋ = ⌈ - {f}_{r} ( δ t - δ {τ}_{0} ) ⌉$$

the terms having fᵣ(δt−δτ) as numerators cancel out. This is corresponds to having δτ matching the shift on the left side of the gap (or one of its periodicities).

Similarly, when fᵣ(δt+δg−δτ) is an integer, we have

$$- {f}_{r} ( δ t + δ g - δ {τ}_{0} ) = ⌊ - {f}_{r} ( δ t + δ g - δ {τ}_{0} ) ⌋ = ⌈ - {f}_{r} ( δ t + δ g - δ {τ}_{0} ) ⌉$$

the terms having fᵣ(δt+δg−δτ) as numerators cancel out. This is corresponds to having δτ matching the shift on the right side of the gap (or one of its periodicities).

In practice, identifying these two matches can be done by varying δτ—over a duration of 1/fᵣ from any starting point—while observing the drift of the peaks to the left and right, and noting when and where the first peaks reach their respective closest position to the gap. The spacing between these two closest positions is δg. And δt is given by the matching δτ when the left peak reaches its closest position to the gap.

Note that δt can only be resolved to within 1/fᵣ as before; whereas δg does not have this restriction.

Also note that similar techniques as in the previous section can be used to extend to measure δg and δt for incomplete patterns.

### 5) Layering Moire Effects

While adding additional layers—in application with classic moire effect—to increase amplification is rarely practiced, there is little to prevent doing so. In theory, the goal of increasing amplification can also be achieved in a single moire effect layer by creating reference signal patterns which resembles closer—in frequency—to the target, thus decrease the Δf, which is the amplification factor. In practice, the technology, effort, and resources required in creating such reference signal pattern may be significantly greater than adding another layer—at a much higher frequency (of the resulting moire effect of the first layer). We note, using insights from the frequency domain analysis in the above, that adding filters in between the layers—to remove or reduce the spurious frequency components—can enhance the resulting effect.

For boundary effect proposed in this section, we noted that the amplification factor is tempered with the multiplicative factor of fᵣ. Fortunately, the extension of boundary effect with a gap can be used to add additional layers—each layer adding another multiple to the resulting amplification. We do note that obtaining the gap spacing δg and left offset δt at each additional layer requires taking multiple measurements at different reference offset δτ. However, we also observe that the δg is the result of mismatch δτ and δt in the first layer. We therefore can directly solve for the first layer offset as minimizing the gap spacing δg in the final outcome, which is a simple layer-by-layer optimization. Finally, we observe that, as in layering classic moire effects, adding filters to remove or reduce spurious frequency components can enhance the overall result.

### B. Combining Rotational and Boundary Effect in a Regular Grid

Properly aligning a lithographic layer mask with another—or the accumulation of all previous layers—require both rotational and translational matching.

This can certainly be done with two different sets of patterns.

For example, we may regard the accumulation of all previous layers as the incomplete target pattern, and either use the current layer mask as the incomplete reference pattern or use a complete pattern based on the spacing parameters of the current layer, and apply the rotational moire effect described in the above to detect and measure any rotational mismatches; and then use fixed patterns in the saw lanes (between chip devices on the wafer) for translational alignment.

Alternatively, we may create patterns—also in saw lanes—which takes advantage of the boundary effect as proposed earlier in this section to detect and measure translational mismatch. In doing so, the accumulated layer patterns so far act as the incomplete target pattern on one side of the boundary, while the complete pattern in the saw lanes serves as the pattern on the other side of the boundary.

Perhaps the more interesting approach is to use the entire chip area as incomplete patterns for both rotational and translation alignment—combining the techniques discussed in the above. Doing so not only leads to simplification but also directly bases both types of alignments in the accumulated previous layers. This latter property allows for the possibility of direct optimal placement for the entire chip area—or even subsections of chip area when appropriately supported.

And one technique to do this is by slightly modifying the chip design rule. Specifically, we propose to subdivide each chip's area into vertical and horizontal sections, and vary the basic material strip width in adjacent sections, as in the following:

Step 1: divide the chip area vertically into a equal sections, and similarly divide horizontally into β sections

Step 2: vary the horizontal material strip width in adjacent vertical section by some minimum amount; and similarly vary vertical strips in each horizontal section by some minimum amount. As an example, suppose 30 nm is the nominal strip width, let the first vertical section-which goes through the entire width of the chip—be designed with horizontal strips of width 30 nm, and let the 2^{nd} vertical section be designed with horizontal strips of width 31 nm, and the 3^{rd} vertical section be designed with horizontal strips of width 30 nm, etc. And we do the same for each of the horizontal sections—each of which spans the full height of the chip—and apply the changing width specification to vertical strips.

Note that because each vertical and horizontal strip of material maintains identical width over the entire chip dimension, the impact to chip layer design is minimal. Even the 45-degree connections can still be made with parallel boundaries.

We do note that the resulting device density is impacted by such variability, at

$$30 \times 30 / ( 31.5 \times 31.5 ) = 96.7 \%$$

We may, however, take advantage of the subtle variability of material width—between these sections—by placing more critical parts of the chip in the section with slightly greater material width. This can serve to increase production yield.

The most important consequence is that we can create boundary moire effect across each of the section boundary—in both vertical and horizontal directions for translational alignment. In fact, we can use these boundaries to both align individual sections as well as assisting alignments of adjacent sections or even over the entire chip.

Moreover, the combined variability of both vertical and horizontal material strip width can be used in rotational alignment—also individually in each section as well as assisting alignment in adjacent sections or even globally.

Finally, we note that increasing granularity of alignment can be simply accomplished by suitably increasing α and β—so long as enough repetition in each section is retained to result in sufficient display of resulting moire patterns—to overcome the incompleteness of patterns—for detecting and measuring mismatches.

### C. Combining Rotational and Boundary Effect to Adapt

We can also choose both the horizontal and vertical boundaries to be located in the middle of concentration of more complete vertical and horizontal strip patterns-within a certain range of areas—to facilitate better detections and measurements. Such selections can then be incorporated into their detections—on a chip-by-chip basis instead of at regular spacing—for alignment and metrology purposes.

### V. Examples of Alignment Techniques

According to the techniques described above, in one aspect, a method is provided for translationally aligning an object to a reference frame. The object can be a semiconductor wafer, or a portion of a wafer having thereon a group of chips that may be partially fabricated, or a single partially fabricated chip, or one or more sections of a chip. The translational alignment is performed along one or more axes, e.g., X, Y, and/or Z axes. To this end, a region of the object is selected, and a first image is obtained from the selected region. In some cases, the selected region can be the entire object. The first image includes two patterns, both along a first axis, which can be any of the X, Y, and Z axes. The first pattern along the first axis (called first-axis first pattern) is an image pattern (e.g., a photograph) of elements spaced apart along a first-axis first grid. The first-axis first grid is a periodic first grid along the first axis, and has a period (called first-axis first period) denoted P0_0.

The second pattern along the first axis (called first-axis second pattern) is also an image pattern (e.g., a photograph) of elements. These elements are spaced apart along a first-axis second grid. The first-axis second grid is a periodic second grid along the first axis, and has a period (called first-axis second period) denoted P0_1. The two periods are slightly different, i.e., they differ from each other by 20%, 10%, 6%, 3%, 1%, etc. The two patterns may be represented by a composite pattern, such as that represented by (22), where f₀=1/P0_0, and f₁=1/P0_1. When the object is a wafer, one or more chips, or portion(s) of a chip, the elements can be metal lines, polysilicon lines, lines or depositions of p-type, n-type, undoped, or otherwise doped silicon. In other cases, the elements may be formed using other materials.

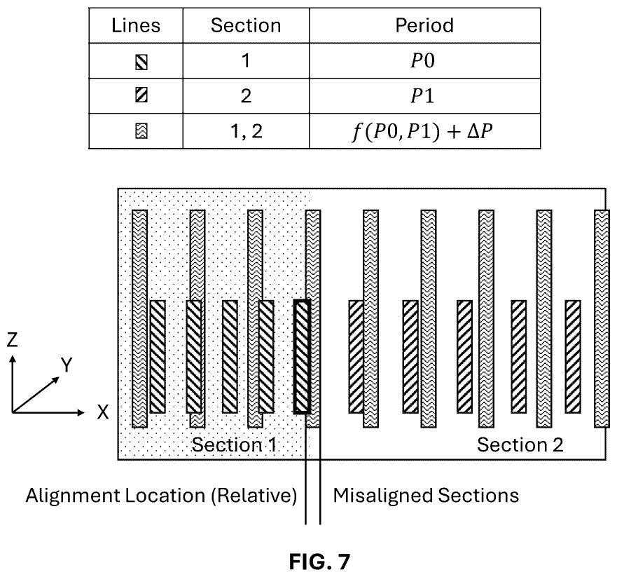

FIG. 7 schematically depicts a rectangular region of an object. The first-axis first and second patterns are adjacent along the first axis, e.g., along the X axis, as shown in FIG. 7. Moreover, the two patterns correspond, respectively, to two adjacent sections of the region along the first (e.g., X, Y, or Z) axis, depicted as Section 1 and Section 2. Section 1 is shaded using a dot pattern and Section 2 is unshaded. In FIG. 7, the line segments having a fill pattern of lines slanting down from left to right indicate the first-axis first pattern. The line segments having a fill pattern of lines slanting up from left to right indicate the first-axis second pattern. In FIG. 7, both of these patterns are periodic, but this is not necessary; either or both patterns can be incomplete.

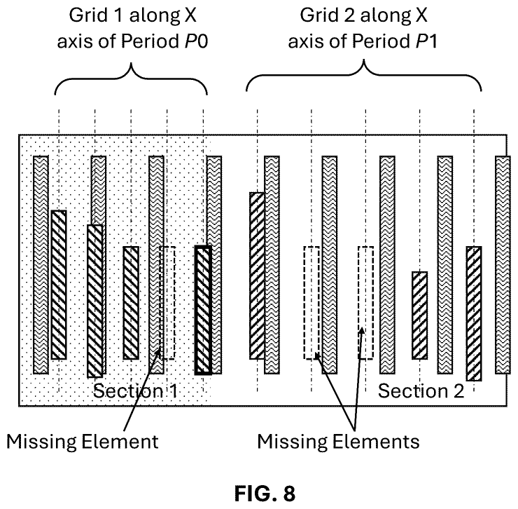

For example, FIG. 8 schematically shows the same rectangular region shown in FIG. 7. The region depicted in FIG. 8 has the same two sections, Section 1 and Section 2, that are depicted in FIG. 7. FIG. 8 depicts two periodic grids, Grid 1 and Grid 2, along the first (e.g., X, Y, or Z) axis corresponding, respectively, to Section 1 and Section 2. The period of Grid 1 is P0, which can be the above-described first-axis first period P0_0. The period of Grid 2 is P1, which can be the above-described first-axis second period P0_1.

The elements forming the first-axis first pattern (such as that seen in FIG. 7) are spaced apart along Grid 1. But the disposition of the elements itself is not periodic, because one element of the first-axis first pattern is missing. Moreover, the elements of the first-axis first pattern do not have the same height/length, and they are not aligned at the top. They are, however, disposed over Grid 1.

The elements forming the first-axis second pattern (such as that seen in FIG. 7) are spaced apart along Grid 2. In this case also the disposition of the elements itself is aperiodic, because two elements of the first-axis second pattern are missing. Like the elements of the first-axis first pattern, the elements of the first-axis second pattern do not have the same height/length, and they are not aligned at the top. They are, however, disposed over Grid 2. The first-axis first and second patterns depicted in FIG. 8 are referred to as incomplete patterns, and are discussed above in Section III.C.

It should be understood that FIGS. 7 and 8 are illustrative only. In general, the first-axis first and second patterns can have any number of elements, e.g., 4, 8, 10, 16, 32, or more. Furthermore, the number of missing elements can be as few as one, or larger, e.g., 2, 5, 10, 20, etc. With respect to the corresponding grid, one or more consecutive elements can be missing. Also, the elements may not be aligned at the top, at the bottom, or at the top and bottom, and may be broken in the middle.

The method for translationally aligning the object further includes obtaining or generating a reference pattern of elements corresponding to the first (e.g., X, Y, or Z) axis. That reference pattern, called first-axis reference pattern, is a pattern of elements that are spaced apart along the first axis and that are disposed periodically at a period called first-axis reference period P0_r. The period P0_r is a function of the first-axis first period P0_0 and/or the first-axis second period P0_1, along with a perturbation ΔP, which is suitable chosen, often a fraction of P0_0 or P0_1. The function can be the average, the weighted average, etc., and AP can be negative, zero, or positive. The first-axis reference pattern may span the first and second sections substantially entirely (e.g., 60%, 75%, 80%, 95%, or more) along the first (e.g., X, Y. or Z) axis. The first-axis reference pattern need not be obtained or generated using an image of physical elements. It can be a synthetic pattern, and may be represented by (23), where fᵣ=1/P0_r.

A first-axis moire pattern, i.e., a moire pattern corresponding to the first (e.g., X, Y, or Z) axis, is generated by a superimposition of the first-axis reference pattern of elements with the first image, i.e., the composite pattern that includes the first-axis first and second patterns of elements. The superimposition can be accomplished via physical superimposition of the first-axis reference pattern and the composite pattern, or synthetically, e.g., by representing the first-axis reference pattern and the composite patterns digitally, as respective frequency domain signals, using Fourier analysis of the respective patterns, and by multiplying the frequency domain signals. In this superimposition, the composite pattern, that includes the first-axis first and second patterns obtained from the image of the selected region, is represented as a composite signal represented by (22).

The first-axis moire pattern includes two sets of peaks. The first set of peaks (or troughs) correspond to the superimposition of the first-axis reference pattern and the first-axis first pattern. These peaks may be denoted L₁, L₂, . . . . L_{M}. The second set of peaks correspond to the superimposition of the first-axis reference pattern and the first-axis second pattern. These peaks may be denoted R₁, R₂, . . . . R_{N}. The method for translationally aligning the object further includes identifying one or more peaks in the first-axis moire pattern, and computing or measuring a first-axis moire pattern distance between: a first-pattern first peak and a second-pattern first peak. The first-pattern first peak can be any peak Lᵢ, i∈[1,M]. The second-pattern first peak can be any peak Rⱼ, j∈[1,N]. The first-axis moire pattern distance is a distance between two observed corresponding peaks Lₖ, Rₖ, for any k∈[1,K], K=min(M,N). This distance is represented by ΔT in any one of (32)-(35). Which of these four equations applies is determined by the values of P0_0, P0_1, and P0_r.

In this context, “observed” does not necessarily mean an observation by a human or a visual observation, though a suitable optical instrument can be used. As noted above, the first-axis moire pattern (and other moire patterns discussed herein) can be generated either by physical superimposition or synthetically, as described above. Therefore, in some cases, the observation, detection, and/or identification of the peaks in such moire patterns can also be performed using signal transformation and/or processing techniques.

The final step is to determine a first-axis displacement for aligning the object to the reference frame along the first axis based on the first-axis moire pattern distance. The first-axis displacement is represented by δt in the applicable one of (32)-(35). Using the applicable one of (32)-(35), the first-axis displacement δt is computed from the first-axis moire pattern distance ΔT. In general, the distance δt is the distance of misalignment of the object (or the selected region thereof) along the first axis (e.g., X, Y, or Z axis) with respect to the applicable frame of reference. In many situations, the value of δt is small enough (e.g., on the order of a few nanometers) that it cannot be observed and/or measured directly, in a reliable manner. The moire patterns discussed herein, amplify the misalignment distance δt into the first-axis moire pattern distance Δt that can be measured with sufficient precision so that the calculated misalignment distance δt can be used to perform the required alignment.

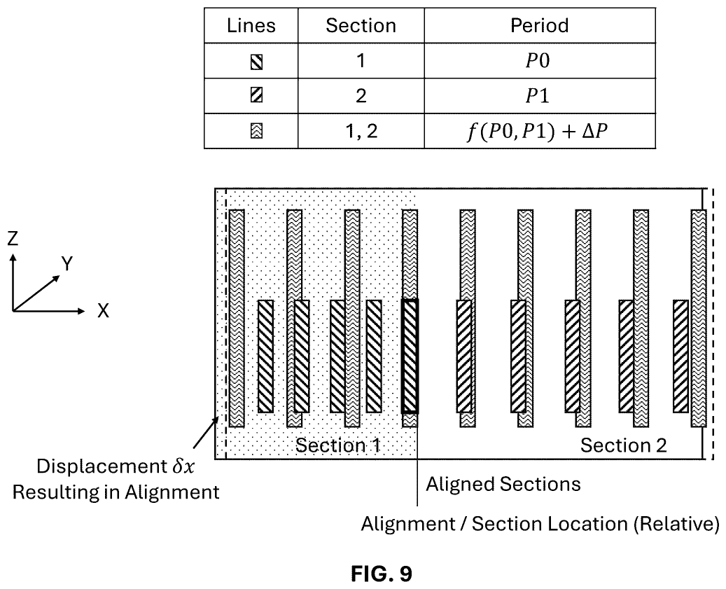

FIG. 9 schematically depicts such an adjustment. Because the first-axis reference pattern is a synthesized pattern, it is aligned precisely, i.e., within an allowable tolerance (e.g., a small fraction of a dimension of the object, such as 5%, 2%, 1%, 0.5%, or even less), to the applicable frame of reference. Once the first-axis displacement δt is computed, the object (or the region thereof) to be aligned to the applicable frame of reference is moved by a distance δt along the first axis (i.e., X axis, as shown in FIGS. 7 and 9). Such movement can be accomplished by physically moving the object. Additionally or in the alternative, a component of the equipment used for manufacturing/fabricating the object can be adjusted such that the object is moved effectively by the distance St.

Prior to determining the first-axis displacement, the first-axis moire pattern distance may be updated based on one or more additional observed peak distances between the two sets of peaks of the first-axis moire pattern. In general, an additional distance can be a distance between a first-pattern second peak, denoted Lₖ′, k′≠k, k′∈[1,K], and a second-pattern second peak, denoted Rₖ′. The updated first-axis moire pattern distance may be computed, e.g., as a simple average or a weighted average of the initially computed peak distance and one or more additional peak distances.

The above-described process for translationally aligning the object to a reference frame can be repeated for additional axes of the frame of reference. An additional axis is referred to as the second axis, and a second image of the selected region is obtained. In some cases, the first image, used for alignment along the first axis, is used as the second image for alignment along the second axis. The second image also includes two patterns, but along the second axis, which can be any of the X, Y, and Z axes. The first pattern along the second axis (called second-axis first pattern) is an image pattern (e.g., a photograph) of elements spaced apart along a second-axis first grid. The second-axis first grid is a periodic first grid along the second axis, and has a period (called second-axis first period) denoted P1_0.

The second pattern along the second axis (called second-axis second pattern) is also an image pattern (e.g., a photograph) of elements. These elements are spaced apart along a second-axis second grid. The second-axis second grid is a periodic second grid along the second axis, and has a period (called second-axis second period) denoted P1_1. The two periods are slightly different, i.e., they vary from each other by 20%, 10%, 6%, 3%, 1%, etc. The first periods, corresponding respectively to the first and second axes (i.e., P0_0 and P1_0, respectively) can be the same or different. Likewise, the second periods, corresponding respectively to the first and second axes (i.e., P0_1 and P1_1, respectively) can be the same or different. The two second-axis patterns may be represented by a composite pattern, such as that represented by (22), where f₀=1/P1_0, and f₁₌₁/P1_1. When the object is a wafer, one or more chips, or portion(s) of a chip, the elements can be metal lines, polysilicon lines, lines or depositions of p-type, n-type, undoped, or otherwise doped silicon. In other cases, the elements may be formed using other materials. The second-axis first and second patterns are adjacent along the second axis, e.g., along the Y or Z axis if the first axis is the X axis. Moreover, the two patterns correspond, respectively, to two adjacent sections of the region along the second axis.

The method for translationally aligning the object further includes obtaining or generating another reference pattern of elements corresponding to the second axis. That reference pattern, called second-axis reference pattern, is a pattern of elements that are spaced apart along the second axis and that are disposed periodically at a period called second-axis reference period P1_r. The period P1_r is a function of the second-axis first period P1_0 and/or the second-axis second period P1_1, along with a perturbation AP, which is a fraction of P1_0 or P1_1. The function can be the average, the weighted average, etc., and AP can be negative, zero, or positive. The second-axis reference pattern may span the first and second sections substantially entirely (e.g., 60%, 75%, 80%, 95%, or more) along the second axis. Like the first-axis reference pattern, the second-axis reference pattern is not obtained or generated using an image of physical elements. Rather it is a synthetic pattern, and may be represented by (23), where fᵣ=1/P1_r.

A second-axis moire pattern, i.e., a moire pattern corresponding to the second axis, is generated by a superimposition of the second-axis reference pattern of elements with the first image, i.e., the composite pattern that includes the second-axis first and second patterns of elements. The superimposition can be accomplished by computer emulation, where the composite pattern, that includes the second-axis first and second patterns obtained from the image of the selected region, is represented as a composite signal represented by (22).

Like the first-axis moire pattern, the second-axis moire pattern also includes two sets of peaks. The first set of peaks correspond to the superimposition of the second-axis reference pattern and the second-axis first pattern. The second set of peaks correspond to the superimposition of the second-axis reference pattern and the second-axis second pattern. The method for translationally aligning the object further includes identifying one or more peaks in the second-axis moire pattern, and computing or measuring a second-axis moire pattern distance between: a second-pattern first peak and a second-pattern second peak. The second-pattern first and second peaks can be any corresponding peaks in the two sets, respectively. This distance is also represented by ΔT in any one of (32)-(35). Which of these four equations applies is determined by the values of P1_0, P1_1, and P1_r.

Thereafter, a second-axis displacement is computed for aligning the object to the reference frame along the second axis, based on the second-axis moire pattern distance. The second-axis displacement is represented by δt in the applicable one of (32)-(35). Using the applicable one of (32)-(35), the second-axis displacement δt is computed from the second-axis moire pattern distance ΔT. In general, the distance δt is the distance of misalignment of the object (or the selected region thereof) along the second axis (e.g., X, Y, or Z axis) with respect to the applicable frame of reference.

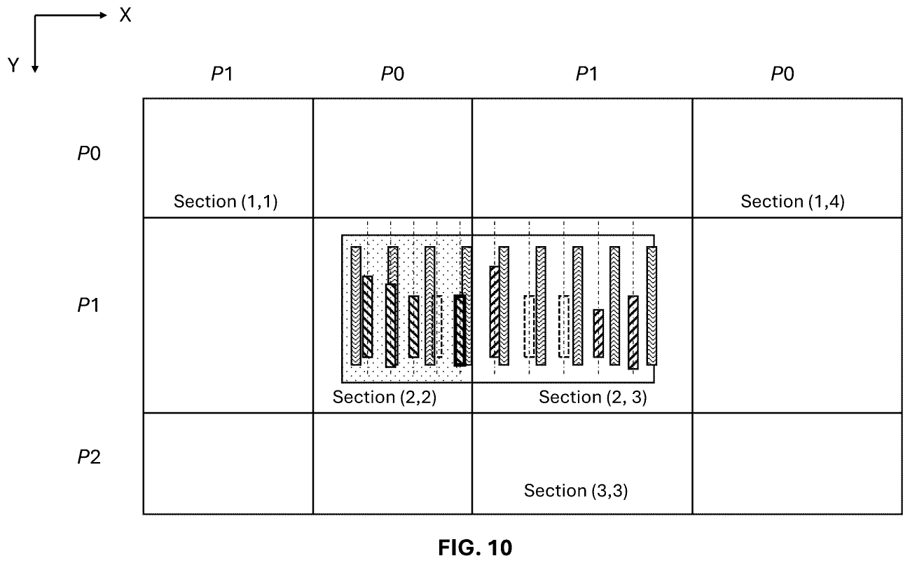

Of the various periods discussed above that are used for aligning the object, one or more periods may be specified or designated to facilitate the alignment. This is illustrated with reference to FIG. 10. In FIG. 10, the outermost rectangle shows a selected region of an object. The selected region need not be, but can be, the entire object. The region is divided into four sections along the X axis and into three sections along the Y axis. It should be understood that FIG. 10 is illustrative, and that the respective numbers of sections along any axis can be any number, e.g., 2, 5, 10, 12, etc.

Each section is associated with a particular grid period along each axis. For example, Section (1, 1) has a grid period P0 along the X axis and a grid period P1 along the Y axis. The grid periods of Section (1, 4) along the X and Y axes are both P0. The grid periods of Section (3, 3) along the X and Y axes are P2 and P1, respectively. While each section along a particular axis can have a distinct grid period along that axis, this is not necessary. It is only required that any pair of adjacent sections along a particular axis have different grid periods along that axis. For example, the two sections depicted in FIG. 7 correspond to Sections (2, 2) and (2, 3) in FIG. 10. For Section (2, 2), the first axis (X axis) grid period, e.g., the first-axis first period, is P0. For Section (2, 3), the first axis (X axis) grid period, e.g., the first-axis second period, is P1.

One or more of these grid periods may not be selectable during the alignment process described herein. In other words, such grid periods may be imposed as constraints. One or more of the other grid periods, however, may be selectable, and may be specified or designated to a particular section to facilitate the alignment processor. For example, if the grid periods for Section (2, 3) are imposed as constraints, the translational alignment method may include designating for the first-axis first section (e.g., Section (2, 2)), the first-axis first period P0_0.

Furthermore, in some cases, an object or a region thereof may not be initially divided into two or more sections along a particular axis, which can make the alignment of that object or region challenging. Therefore, the method for translational alignment may include dividing an object or a selected region thereof into two (or more) sections along one or more axes. A suitable grid period may be specified for one or more of the formed sections along one or more axes. Thus, in general, the translational alignment method may include one or more of: (i) designating for the first-axis first section the first-axis first period P0_0; (ii) designating for the first-axis second section the first-axis second period P0_1; (iii) designating for the second-axis first section the second-axis first period P1_0; or (iv) designating for the second-axis second section the second-axis second period P1_1. These periods may be designated based on the applicable design rules for the object to be aligned.

In another aspect, a method is provided for rotationally aligning an object to a reference frame. The method includes obtaining an image from a region of the object, where the image includes a first-axis observed pattern of elements disposed over a first-axis grid along a first axis. The first-axis grid has a first-axis period P0. As an example, the value of P0 can be d0 (or d1) shown in FIG. 2. The first-axis observed pattern is aperiodic or incomplete, such as that shown for each section depicted in FIG. 8.

The method also includes generating a first-axis reference pattern of elements that are spaced apart periodically along the first axis. The period of the first-axis reference pattern, denoted P0r, is selected such that a first-axis moire pattern is measurable at a specified sensitivity of a measuring instrument, as described below. As an example, the value of P0r can be d1 (or d0). The first-axis moire pattern is formed by a superimposition of a first-axis reference pattern with the first-axis observed pattern. The first-axis reference pattern may be generated synthetically. The first-axis moire pattern may be generated physically or may have its desired characteristic captured via transformations and/or signal processing techniques.

In general, the spacing between elements forming the first-axis observed pattern, i.e., the period P0 (which can be d0 or d1, as shown in FIG. 2), may not be measurable by an available measurement instrument. The spacing of the lines of the first-axis moire pattern, which is the distance ∥\vec{AH}∥ (also denoted Δdᵣ in (8)) shown in FIG. 2, however can be measurable by the available measurement instrument. Once the period of the first-axis reference pattern, Por, is selected such that a first-axis moire pattern is measurable, a first-axis angle of moire lines from the first-axis moire pattern, relative to the first-axis reference pattern, is also measurable. Thus, a first-axis spacing and/or the first-axis angle of moire lines from the first-axis moire pattern can be measured.

Accordingly, the method for rotational alignment further includes computing or measuring a first-axis spacing between moire lines from the first-axis moire pattern and/or a first-axis angle of the moire lines from the first-axis moire pattern. The first-axis spacing is denoted Δdᵣ; the first-axis angle is denoted δᵣ which is computed using (9), where the first-axis angle ∠ABC can be measured from the first-axis moire pattern with respect to the reference pattern. Finally, the method includes computing from this first-axis spacing or the first-axis angle of moire lines an angular displacement for rotationally aligning the object to the reference frame. The angular displacement, denoted α, can be computed from the first-axis spacing using (8) or from the first-axis angle using (12), for exact calculation or (14), for an approximate calculation. The estimates of the angle α can be improved by combining, e.g., averaging, both the computations based on the first-axis spacing and the first-axis angle.

The above-described method can be repeated for a second axis, where the two angular displacements corresponding to the two axes may be combined, e.g., averaged, to yield a final value of the angular displacement to be used to perform the rotational alignment. A different image of the selected region may be used when the method is repeated for the second axis. Alternatively, the first image may be reused, if the first image includes an additional pattern of elements disposed over a second-axis grid along the second axis. The additional pattern is called a second-axis observed pattern. The period of the second-axis grid is called a second-axis period and is denoted P1. The value of P1 may be the same as or different from that of P0. The pattern of elements disposed over the second-axis grid can be, but need not be, aperiodic or incomplete.

The method for rotational adjustment may include selecting a second-axis reference period P1r, such that a second-axis moire pattern is measurable at the specified sensitivity. The second-axis moire pattern is formed by a superimposition of a second-axis reference pattern of elements, spaced apart periodically along the second axis and at the second-axis reference period P1r, with the second-axis observed pattern. The method also includes computing or measuring a second-axis spacing and/or a second-axis angle of moire lines from the second-axis moire pattern, e.g., using (8), (12), and/or (14). Computing the angular displacement is based on, at least in part, both the first-axis angle of moire lines and the second-axis angle of moire lines.

The selected region can be the entire object, i.e., the size of the selected region is the same as that of the object. The object can be a semiconductor wafer, or a portion of a wafer having thereon a group of chips that may be partially fabricated, or a single partially fabricated chip, or one or more sections of a chip. When the object is a wafer, one or more chips, or portion(s) of a chip, the elements can be metal lines, polysilicon lines, lines or depositions of p-type, n-type, undoped, or otherwise doped silicon. In other cases, the elements may be formed using other materials. The specified sensitivity may correspond to an instrument sensitivity of an instrument used for measuring the moire pattern. In some cases, the method may include specifying: the first-axis observation pattern period P0, or the second-axis observation pattern period P1, or both P0 and P1.

The techniques described herein are not limited to the fabrication of wafers and semiconductor chips. They are, nevertheless, well suited for the fabrication of wafers and chips. Chips to be fabricated typically include different types of sub-circuits, such as, e.g., a general-purpose processor, a vector processor, RAMS of different types including registers, static RAMS (SRAMs), dynamic RAMS (DRAMs), special-purpose arithmetic processing units, and units implementing specialized logic, clock generators, etc. A typical RAM includes a storage array and address/decoder logic. Each of these sub-circuits includes components (also called elements) fabricated using semiconductor material, local interconnect, and sections of global interconnect that may interconnect different sub-circuits. The semiconductor material generally includes undoped, n-type, and/or p-type semiconductor material, polycrystalline semiconductor material, and n-type and p-type wells within which semiconductors devices can be formed. The local and global interconnects generally include polysilicon and metal lines.

Typically, the fabrication of a chip is based on a list of pre-specified design rules. Examples of such design rules include the minimum width of a region of a particular type of (e.g., n-type, p-type, n-well, p-well, etc.) semiconductor region, the minimum spacing between two adjacent semiconductor regions of the same type, the minimum spacing between two adjacent semiconductor regions of two different types, where the minimum spacing can change based on the type of the semiconductor material. Additional design rules include the minimum width of a local interconnect metal line, or a global interconnect metal line, the minimum spacing between such metal lines, etc. It should be understood that the above-listed design rules are examples only and that this listing should not be understood as comprehensive.

These design rules can be empirical, and are often based on the limitations of the physical properties of the material involved and/or the fabrication process and/or equipment. For example, the fabrication equipment to be used may not be able to form semiconductor layers or metals lines less than the specified respective widths, or may need to leave a certain minimum spacing between two layers or lines so as to avoid merging of the two layers or lines together. In order to maximize the utilization of the available chip area for the implementation of the circuitry of interest, the design rules are typically devised to minimize unused space while ensuring that the intended circuitry can be fabricated in an error-free manner.

Different kinds of sub-circuits often have different size and/or performance requirements. Based on the different performance requirements, different sub-circuits may even be operated at different voltages and/or clock frequencies. As one example, it may be desired that the storage portion of a DRAM is as small as possible, packing as many individual storage cells into a unit area as possible. On the other hand, it may be desired that the address decoder sections of that DRAM operate as fast as possible, which may require semiconductor layers having width(s) greater than those sufficient for a relatively slower operation of the address decoders. As another example, it may be desired that the local interconnects of a vector processor or an arithmetic processor handle high power requirements of these processors, resulting in high current densities within the local interconnects.

As noted above, the design rules are generally directed to ensuring error-free fabrication while maximizing usage of the chip area, and are generally not directed to circuit performance. Circuit designers, however, often take into account the applicable size/performance goals or constraints. Accordingly, they may choose various width, length, and spacing parameters corresponding to the semiconductor and/or metal layers to be used in a particular sub-circuit based on, at least in part, the applicable size/performance requirements, while obeying the applicable design rules. The discussion below collectively refers to the width, length, and spacing parameters, and the related circuit-placement parameters, as dimension parameters or dimension rules.

Semiconductor wafers (and the chips thereon) are generally fabricated in a sequence of fabrication steps, where different elements of the overall circuitry are formed in a layer-by-layer manner in one or more steps of the overall sequence of fabrication steps. It is critical that the wafers/chips are aligned to a selected frame of reference in each of the fabrication steps. Otherwise, a misalignment of a wafer/chip can cause a misalignment of the layers of a particular element, resulting in a sub-optimal or even failed fabrication of that element. This may further result in the failure of a particular fabrication step and/or of the wafer/chip.

Furthermore, modern wafers, and even individual semiconductor chips, are large enough and/or have a high enough density of different types of elements forming various sub-circuits, that a single layer of wafer or an individual chip is often not formed in a single step. Rather the wafer or an individual chip are divided into several sections (e.g., 2, 4, 10, 16, etc.). Each fabrication step is divided into sub-steps, and in each sub-step, a layer of a particular section is formed. In this process, it is essential to align the different sections of a wafer/chip as precisely as possible. Otherwise, section-by-section alignment can result in the formation of sub-optimal or even failed sub-circuits.

One technique used to accomplish layer-by-layer and section-by-section circuitry is to fabricate in each step and sub-step dummy structures, that are periodic in nature, on the wafer, each chip, and/or each section of a chip. These dummy structures do not contribute to the function of the chips on the wafer. They are used only for the purpose of alignment. In some cases, the dummy structures are provided on the wafer, in scribe lines, i.e., trench-like regions between adjacent rows and columns of the chips on a wafer, where cutting is performed once the entire circuitry of the chips is formed, to separate individual chips from each other. The dummy structures in the scribe lines do not take up chip area, but they may not facilitate fine alignment that is generally needed as the individual semiconductor devices become smaller and smaller. In particular, the dummy structures in scribe lines are generally considered unsuitable for facilitating section-by-section alignment of different sections of an individual chip. To facilitate fine alignment in such situations, dummy structures can be added on each chip and even within each section of a chip. The on-chip dummy structures, however, take up chip area that can otherwise be used for the formation of desired circuitry, and may create complex placement and/or routing constraints for the desired circuitry. It is therefore generally desirable to minimize the number of on-chip dummy structures. But, this can make the layer-by-layer and section-by-section alignment tasks difficult and/or more error prone.

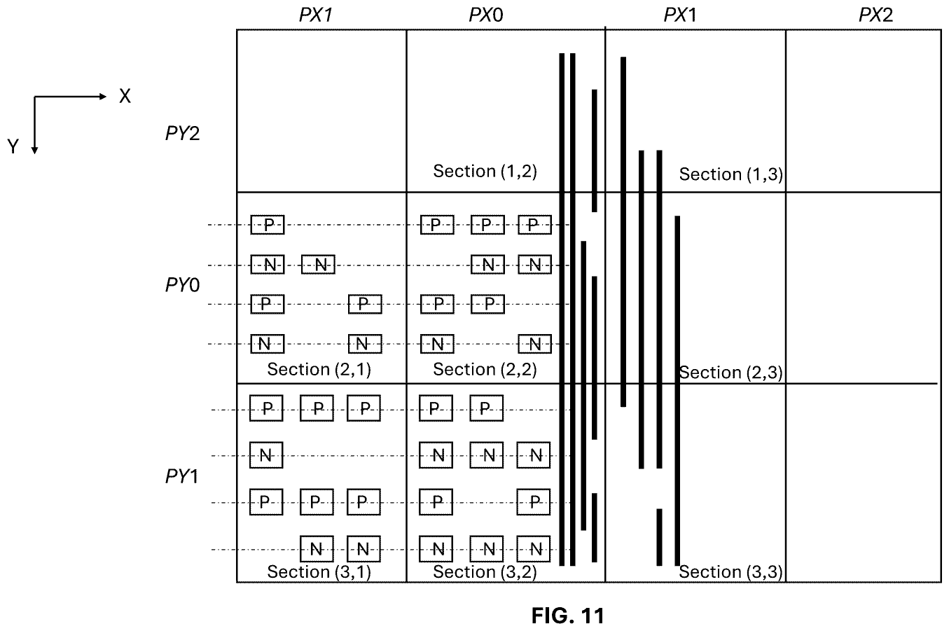

Certain techniques described herein facilitate fine-grain, layer-by-layer and section-by-section alignment without using any dummy structures. Instead, one or more of the above-described design rules, dimension rules in particular, are modulated (interchangeably referred to as modified) such that the circuit elements fabricated using different design rules lend themselves to the application of various fine-gram alignment techniques described herein. This is illustrated referring to FIG. 11. In FIG. 11, a chip to be fabricated is divided along the X and Y axis into a grid of 12 sections. Sections (2, 1) through (3, 2) schematically depict rows and columns of p-type and n-type semiconductor materials, forming arithmetic, logic, and/or storage components of the chip circuitry. Sections (1, 2) through (3, 3) depict global interconnect lines.

It should be understood that in FIG. 11, the number of sections 12 is used as an example only. In general, a chip may be divided into as few as one and as many as 10, 16, 20, or even more sections along any particular axis. The p-type and n-type material may be formed in different configurations, such as in an interleaving manner, perpendicular to each other, having different lengths and/or widths, etc. Moreover, for simplicity of illustration, all of the elements in each section are not shown. For example, all sections may have semiconductor layers, local interconnect, and portions of local and global interconnect along X, Y, and/or Z axes. It should also be understood that the numbers of rows and columns of the semiconductor material and the number of lines and length of the global interconnect as shown are examples only, and are not limiting.

As noted above, the chip-design rules typically specify the minimum width for each of the p-type and n-type semiconductor layers and the metal lines. The design rules also specify the minimum distance between two adjacent p-type (or n-type) layers, adjacent p-type and n-type layers, and adjacent metal lines. In Sections (2, 1) and (2, 2), the semiconductor layers are formed according to the specified design rules. In Sections (1, 2) through (3, 2), the metal lines of the global interconnect are formed according to the specified design rules.

In Sections (3, 1) and (3, 2), however, the design rule pertaining to the minimum width of p-type and n-type semiconductor layers is modified or modulated, and the minimum width is increased by a small fraction (e.g., 1%, 2%, 6%, 15%, or more) of the originally specified minimum width. For the simplicity of illustration, only one design rule is modulated, but one or more other design rules can be changed in addition or in the alternative to modifying the above-discussed rule. For example, the minimum spacing between adjacent p-type and n-type semiconductor layers can also be increased. In Sections (1, 3) through (3, 3), the design rule pertaining to the minimum spacing between two adjacent metal lines is modulated, where such minimum spacing is increased by a small fraction (e.g., 1%, 2%, 6%, 15%, or more) of the originally specified minimum spacing. It should be noted that no modulation of a design rule violates the corresponding original design rule. For example, a minimum specified width/spacing can be increased but not decreased below the specified minimum.

The above-described modulation of the design rules can result in changing the period(s) of pattern(s) of elements formed in different sections. For example, in Sections (2, 1) through (3, 2), the alternating rows of p-type and n-type semiconductor layers form a pattern. In Sections (2, 1) and (2, 2), this pattern has a period PY0, as measured between the respective centerlines of the semiconductor layers. Because modified design rule regarding the p-type and n-type semiconductor layers increases the width of the p-type and n-type semiconductor layers in Sections (3, 10) and (3, 2), the period of the semiconductor-layer pattern has changed to PY1. As described above in Section III.A and with reference to FIGS. 7-10, using the two different periods PY0 and PY1, the sections of the chip, the chip as a whole, or even the wafer on which the chip is located can be translationally aligned along the Y axis.

As another example, the metal lines in Sections (1, 2) through (3, 2) also have a pattern. In Sections (1, 2) through (3, 2), this pattern has a period PX0. Because the modified design rule regarding the minimum spacing between adjacent metal lines increases that spacing, the period of the metal-line pattern has changed to PX1. Here again, as described above in Section III.A and with reference to FIGS. 7-10, using the two different periods PX0 and PX1, the sections of the chip, the chip as a whole, or even the wafer on which the chip is located can be translationally aligned along the X axis.

An important benefit of the above-described technique is that the modulation of a design rule may be sufficient to facilitate alignment. No additional, dummy structures that can take up space on the chip and/or interfere with the placement and/or operation of the elements of the desired circuitry are utilized. Such dummy structures are not needed when alignment is performed using the modulated design rules. To facilitate the alignment, it is not necessary to modulate each and every dimension rule. It is also not necessary to apply a modulated design rule to each and every section, or that each section must be designated a unique set of modulated design rules.

In one particular case, an alignment of a wafer, chip, or section can be accomplished without using a dummy periodic structure, by using instead a pattern associated with an actual structure that is aperiodic or incomplete, as described above referring to FIG. 8 and in Section III.C. The corresponding observed pattern would also be aperiodic or incomplete, having a period P0, along a selected axis. A reference pattern that is not incomplete, and instead is periodic, and has a period Pr that is substantially the same as the period P0 (e.g., within a tolerance of 10%, 5%, 2%, 1%, or even less, of the period P0), is selected. The two patterns are subjected to illumination and are superimposed to generate a moire effect. For example, to derive the relative displacement to align the sections, the distance(s) between corresponding peaks/troughs of intensity in the resulting moire pattern are measured. The displacement of the wafer/chip/section that is necessary to achieve the translational alignment along the selected axis can be computed from a distance between corresponding peaks.

In the alternative, the distance(s) between intensity peaks and troughs for different relative displacements can be computed directly via simulation. For example, by representing the observed and reference patterns as sequences of suitable symbols that modulate the illumination according to the respective patterns, and by superimposing (e.g., by convolution) the two sequences. The resulting function of the intensity variation can be used to approximate the intensity variation of the illumination so as to assist in identifying and determining the peaks and troughs in a moire pattern that would result from an actual superimposition of the observed and reference patterns.

As a comparison, a translational alignment can be accomplished without needing two patterns having different periods in two adjacent sections, as described above with reference to FIGS. 7-11. Furthermore, the period P0 can be, but need not be a modulated period. In other words, the period P0 may be based on the originally specified design rules. This technique can be used, however, only in cases where the required displacement for alignment is less than P0/2. The technique described above with reference to FIGS. 7-11 is not so limited. The peak-distance-measurement based technique can also be employed using a dummy structure that can be aperiodic or periodic.

In general, one or more sections may employ the originally specified design rule, i.e., without any modification of the specified rule. An original design rule may be modulated more than once to obtain a first variant, a second variant, etc. A particular variant may be associated with one or more chip axes (e.g., X, Y, and Z axes). No variant may be provided along a particular chip axis, or one or more variants may be provided for any chip axis. Different sections may employ the original design rule, the first variant thereof, the second variant thereof, and so on. It is not necessary however, that the original design rule or a variant thereof be employed by only one section. The original design rule and any variant thereof may be employed by two or more sections. Furthermore, a particular section may employ no modified design rules, only a single modified design rule, two or more modified design rules along the same axis, or two or more modified design rules along different axes. The translational alignment described herein is facilitated when two adjacent sections employ different versions of at least one design rule, where only one or both versions can be modulated versions.

In order to facilitate alignment, the modulation of a design rule must be within a moire limit. In particular, suppose a particular section employs a first version of a design rule, and an adjacent second section employs a second version of that design rule. Either the first or the second version can be the originally specified designed rule, or both versions can be differently modified versions. Two patterns of elements, namely the first and second element patterns, are formed in the two sections, respectively, according to the two respective versions of the design rule. To perform alignment, a reference pattern is selected, and a composite moire pattern is generated by a superimposition of the reference pattern with the first and second element patterns. Such element patterns, reference pattern, and composite moire pattern are described above in Section IV.A and with reference to FIGS. 7-10.

The respective frequencies of the first and second element patterns and the reference pattern are the respective reciprocals of the periods of the first and second element patterns and the reference pattern. These frequencies must be selected such that the respective moire patterns obtained by superimposition of the first and second element patterns, respectively, with the reference pattern are measurable by an available instrument. This generally means that the respective moire patterns corresponding to both the first and second element patterns must have sufficiently large spacing. For each such moire pattern (which together form the composite moire pattern), the respective spacing can be described by a respective application of (3). In practice, the period/frequency of one of the two element patterns (or of the reference pattern) may be known, e.g., from the design rules employed, the layout, etc. The available measurement instrument may identify the minimum spacing that is measurable. Using these known quantities, (3) can be used to determine a period/frequency of the reference pattern and of one of the two element patterns.

In some cases, either or both of the respective moire patterns are not observable. In such cases, the technique described herein can be applied in an iterative manner, as described in Section IV.A.4. In this case, the respective moire patterns generated in the first iteration are not measurable. But, those moire patterns themselves are used as the first and second element patterns for a second (next, in general) iteration. A different reference pattern from that used in the first (previous) iteration is selected for the second (next) iteration, based on the moire limit, and the above described process is repeated, to obtain a new composite moire pattern. Such iterations can be performed one or more times until the composite moire pattern generated in a particular iteration is measurable.

In cases where only one iteration is to be performed, the periods of the first and second element patterns and the reference pattern must be selected so as to provide: (i) a desired translational alignment/adjustment range, and (ii) such that the composite moire pattern generated using these element and reference patterns is measurable. If either of the two versions of the design rule is the originally specified design rule, the period (frequency) of the element pattern corresponding to that version of the design rule is determined by the originally specified design rule itself. Otherwise, all three periods (frequencies) are selectable. Nevertheless, once the period (frequency) of one of the versions of the design rule is specified or selected, the period (frequency) of the reference pattern, and based thereon, and the period (frequency) of the other version of the design rule, can be selected within only a limited range that satisfies the two conditions described above. Similarly, for a given period (frequency) of the reference pattern, the periods (frequencies) of both versions of the design rule can be selected within only a limited range that satisfy the two conditions described above. That range is referred to as a moire limit. It should be understood that the moire limits for different design rules, and different variations/versions thereof, can be different.

The sectioning of a chip as described with reference to FIGS. 10 and 11 can be, though not necessarily be, based on the kinds of sub-circuits included in the chip. For example, the placement of different kinds of sub-circuits in different portions of a chip can be said to divide the chip into corresponding several different sections. As noted above, the different sub-circuits may have different size and/or performance constraints. As such, in some embodiments, the modulation and/or designation of a design rule to a particular section is based on a size and/or performance constraint for the sub-circuit corresponding to that section. For example, suppose a particular section includes a sub-circuit where minimizing the potentially adverse effects of switching noise is desirable. For such a section, employing a design rule that specifies an increased spacing between adjacent metal lines forming a bus may be beneficial. In another section, if the size and/or power consumption constraints are important, employing an original design rule that specifies the minimum widths of semiconductor layers may be beneficial.

A certain subset of design rules that may contain one or more original design rules and/or one or more modulated design rules (modified as described herein) may be determined to be beneficial for a particular design goal, such as size, performance in terms of speed, power consumption, noise tolerance, fabrication yield, etc. There can be more than one such subsets, corresponding to different kinds of sub-circuits and/or different types of design goals. Such subsets of design rules may be designated to different sections of a chip. The other sections of the chip may employ the originally specified design rules or variants thereof, where those variants are generated as described above.

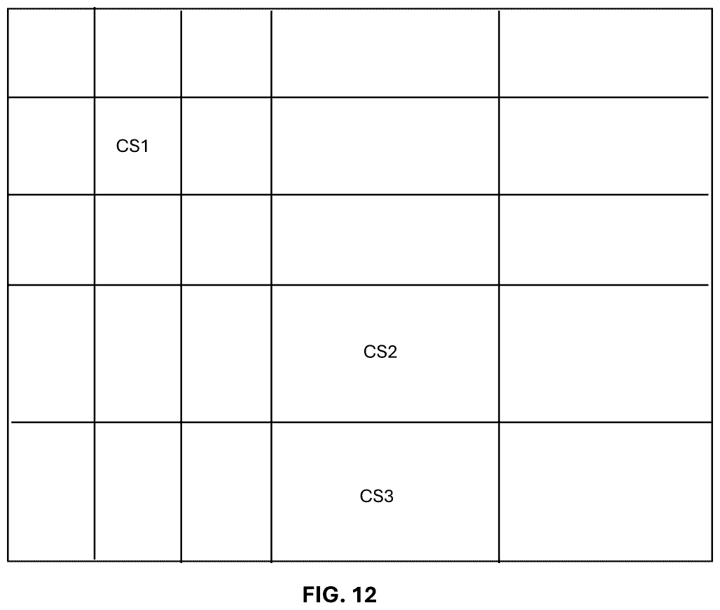

For example, FIG. 12 schematically depicts a chip divided into a grid of 25 sections. Three of these sections are critical in terms of size and/or performance requirements. The numbers 25 and 3 are illustrative only and are not limiting. To each of the critical sections, denoted CS1, CS2, and CS3, a corresponding subset of design rules may be applied. The corresponding subset of design rules is selected so as to meet the specified size and/or performance requirements of the corresponding critical section. Such a subset may include one or more original design rules and/or one or more modulated design rules. The different subsets of design rules can be entirely different, partially overlapping, or identical. Identical subsets of design rules cannot be applied to adjacent critical sections, however, e.g., CS2 and CS3, when the techniques described herein are used for section, chip, and/or wafer alignment.

The non-critical sections may employ all original design rules, all modified versions of the design rules, or a combination of one or more original rules and one or more modified versions of the design rules. The alignment techniques described herein only requires that for a pair of adjacent sections along a particular chip axis, whether or not critical, two different versions of at least one design rule must be employed, respectively, by the two sections of the pair, to facilitate section/chip/or wafer alignment along that chip axis. One or the two versions of the design rule can be the originally specified design rule, or both versions can be differently modulated versions.

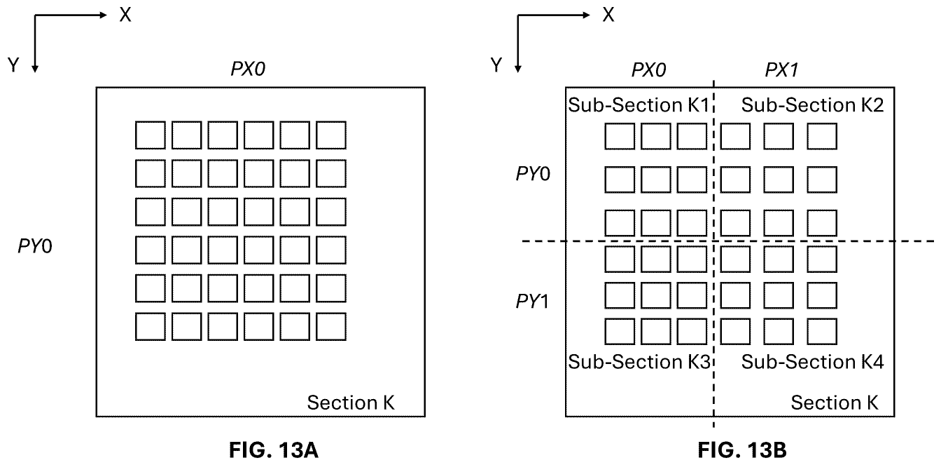

The above described technique can also be used to form sub-sections. This can be beneficial in cases where a particular sub-circuit (e.g., the storage section of a RAM, a multi-bit bus (e.g., 64-bit or 128-bit bus)) is large, resulting in a corresponding section that is so large along at least one chip dimension such that sub-sectioning of that section can be beneficial or even necessary for an error-free chip fabrication. This is illustrated referring to FIGS. 13A and 13B. FIG. 13A schematically depicts Section K of a chip that includes an array of storage elements. The placement of the storage elements in the array forms an X-axis pattern along the X axis, having a period PX0 and a Y-axis pattern along the Y axis, having a period PY0. It should be understood that the number of rows and columns of the array are illustrative only and not limiting.

To facilitate a more precise alignment of Section K with its neighboring section(s) (not shown) and/or a more precise alignment of the chip/wafer, Section K is divided into four subsections, as shown in FIG. 13B. Here again, the four subsections are illustrative only. In general, a particular section can be divided along only one axis into two or more subsections, or along two or all three axes into two or more subsections along each axis. In Subsections K2 and K4, the period of the pattern of the array along the X axis (e.g., a spacing along the X axis between the successive columns of elements) is changed from PX0 to PX1. In Subsections K3 and K4, the period of the pattern of the array along the Y axis (e.g., a spacing along the Y axis between the successive rows of elements) is changed from PY0 to PY1. Thus, for each pair of adjacent sections along the X axis and along the Y axis, the periods of the corresponding patterns are different, which can facilitate a translational alignment as described herein.

Accordingly, in another aspect, a method is provided for employing one or more design rules for fabricating computer chips. The method includes obtaining a set of design rules for a particular parameter of chip elements of a particular type. The particular type of chip elements can be, e.g., n-type, p-type, or undoped semiconductor layer, n-type or p-type well, a metal line, a polycrystalline line, etc. A particular parameter of such elements can be the width of a layer, a spacing between adjacent elements, a spacing between the respective centerlines of the adjacent elements of the particular type, etc. The set of design rules includes an original dimension rule corresponding to the particular parameter of the chip elements of the particular type, and a corresponding first variant dimension rule. The first variant dimension rule is obtained by varying the original dimension rule within a moire limit.

In addition, a chip to be fabricated is divided into several adjacent sections along a selected chip axis (e.g., the X, Y, or Z axis), where the several adjacent sections include a first section and a second section. The method further includes designating or employing for particular parameter of the chip elements of the particular type a first selected dimension rule and a second selected dimension rule, which is different from the first selected dimension rule. The first and second selected dimension rules are obtained from the set of design rules for the particular parameter of the chip elements of the particular type. The first selected dimension rule is applied to the design of the chip elements of the particular type in the first section. The second selected dimension rule is applied to the design of the chip elements of the particular type in the second section.

In some embodiments, the first selected dimension rule is the original dimension rule, and the second selected dimension rule is the first variant dimension rule. The set of design rules may also include a second variant dimension rule obtained by varying the original dimension rule within the moire limit, where the second variant dimension rule is different from the first variant dimension rule. The first selected dimension rule can be the first (or second) variant dimension rule, and the second selected dimension rule can be the other, i.e., the second (or first) variant dimension rule. The original dimension rule may specify a width of an instance of the chip elements of the particular type. The original dimension rule may also specify a spacing (e.g., a minimum/maximum spacing) along the selected chip axis between two consecutive instances of the chip elements of the particular type, or a spacing between respective centerlines of two consecutive instances of the chip elements of the particular type, where those instances are to be placed along the selected chip axis.

In some embodiments, the several adjacent first-axis sections include a third first-axis section. For these embodiments, the method further includes designating for the particular parameter of the chip elements of the particular type, for the third first-axis section, a third selected dimension rule. In some cases, the second first-axis section is disposed between the first first-axis section and the third first-axis section, and the third selected dimension rule is the original dimension rule. The set of design rules may include a third variant dimension rule (in addition to or instead of the second variant dimension rule) obtained by varying the original dimension rule within the moire limit. The third variant dimension rule is different from the first variant dimension rule, and if included in the set of design rules, the second variant dimension rule. The third selected dimension rule is the third variant dimension rule.

In some embodiments, the first section includes circuitry having a specified size and/or performance constraint. In this case, designating for the chip elements of the particular type, for the first section, the first selected dimension rule may be based on, at least in part, the specified size and/or performance constraint. The chip to be fabricated may include a number of sub-circuitry sections. As such, the method may further include dividing the chip to be fabricated into a number of grid sections along a grid. The grid has a first axis, which is the same as the selected chip axis and a second axis perpendicular to the first axis. The total number of grid sections may be determined based on, at least in part, the total number of the sub-circuitry sections. The chip is divided into the grid sections such that a first grid section includes the first section of the chip along the selected chip axis. In cases where the chip is divided into a number of grid sections, the first selected dimension rule may be based on, at least in part, a size and/or performance requirement of a sub-circuitry section corresponding to the first grid section.

In some embodiments, the method includes designating for the chip elements of the particular type, for the first grid section, a second-axis dimension rule. The second-axis dimension rule can be a second original design rule obtained from the list of specified design rules. In some cases, the second-axis dimension rule may be based on, at least in part, a size and/or performance requirement of a sub-circuitry section corresponding to the first grid section. In this case also, the second-axis dimension rule can be the second original design rule. In some other cases, the second-axis dimension rule is obtained by varying a second original dimension rule from the list of specified design rules within the moire limit. The above-described operations can be performed by a circuit/chip designer during a chip-design process, e.g., during layout generation. Alternatively, or in addition, the above-described operations may be performed at a chip-fabrication facility, prior to and/or during the fabrication of a chip based on a provided initial layout of the chip.

It was noted above that a benefit of the design-rule-based techniques described herein is that they can use the structures on a chip that are formed to implement, at least in part, the desired function(s) of the chip, for alignment of the chip and/or its sections, and that dummy structures are not needed. These techniques, nevertheless, can be used to form dummy structures used for alignment. For example, one or more sections of a chip may not include structures that implement, at least in part, the desired function(s) of the chip and that have elements placed on a periodic grid. In some cases, such a structure may be designated to a particular section, but the pattern of the elements of that structure may be too small (e.g., may have very few elements) or may have a substantial number of inconsistencies. In other cases, a particular section may be adjacent to one or more critical sections, and have space. In such cases, a dummy structure of elements, e.g., a sequence of substantially parallel metal lines, a sequence of stripes of semiconductor material, etc., may be provided using the original design rule(s) and/or one or more variants of such design rule(s). Such a dummy structure, together with another dummy structure or structures on the chip that is formed to implement, at least in part, the desired function(s) of the chip, can be used, as described herein, to facilitate chip/section alignment.

Accordingly, in yet another aspect, a method is provided for facilitating chip alignment via a chip-layout synthesizer, by incorporating within or providing to the chip-layout synthesizer (e.g., within or to a module therein) one or more variant design rules for fabricating computer chips. The method includes selecting, for a particular parameter of chip elements of a particular type, an original design rule that includes an original dimension rule. The method also includes generating a first variant dimension rule obtained by varying the original dimension rule within a moire limit. The particular type of the chip elements can be a metal line, a p-type semiconductor layer, an n-type semiconductor layer, a polycrystalline semiconductor layer, a p-type well layer, an n-type well layer, or an undoped semiconductor layer. The particular parameter can be a width of an instance of the chip elements of the particular type; a spacing along a selected chip axis between two consecutive instances of the chip elements of the particular type, where the two instances are to be placed along the selected chip axis; or a spacing along the selected chip axis between respective centerlines of two consecutive instances of the chip elements of the particular type, where the two instances are to be placed along the selected chip axis. The method may also include incorporating within or providing to the chip-layout synthesizer a second variant dimension rule obtained by varying the original dimension rule within a moire limit. The second variant dimension rule is different from the first variant dimension rule.

For another different parameter of the chip elements of the particular type, there may be another original rule, that may be selected in some embodiments. The method may include incorporating within or providing to the chip-layout synthesizer another first variant dimension rule that is obtained by varying the other original dimension rule corresponding to the other parameter, within a moire limit. Likewise, for the particular parameter but another type of chip elements, there may be yet another original rule, that may be selected in some embodiments. The method may include incorporating within or providing to the chip-layout synthesize yet another first variant dimension rule that is obtained by varying, within a moire limit, the yet another original dimension rule corresponding to the particular parameter but for the other type of chip elements.

In some embodiments, the chip-layout synthesizer includes a placement module, a routing module, and/or a design-rule-checking (DRC) module. The original dimension rule and the first variant dimension rule may be applied by the placement module and/or the routing module. Additionally or in the alternative, the original dimension rule and the first variant dimension rule may be enforced by the DRC module. The chip-layout synthesizer may be used by a circuit/chip designer during a chip-design process, e.g., during layout generation. Alternatively, or in addition, the chip-layout synthesizer may be used at a chip-fabrication facility, prior to and/or during the fabrication of a chip, where the chip-layout synthesizer may modify an initial layout of the chip by applying one or more variant or modified design rules.

In some embodiments, a sectioning rule is provided to or incorporated within the chip-layout synthesizer. The sectioning rule may specify that a chip be partitioned into a number of sections (e.g., 2, 3, 5, 10, etc.), that are respectively adjacent along a chip axis. An example of such sectioning along the X and Y axes is described above with reference to FIG. 12. The sectioning rule may also designate for each of the sections along a particular chip axis a respective dimension rule that, as described above, specifies a particular parameter of the chip elements of a particular type. For example, the chip may include first and second sections that are along a particular chip axis and that are adjacent. First and second dimension rules may be designated, respectively, to the first and second sections, where the second dimension rule is different from the first dimension rule.

In some embodiments, the first dimension rule includes the original dimension rule, and the second dimension rule includes the first variant dimension rule. The sectioning rule does not mandate that each section be associated with a unique dimension rule. For example, the chip may have three respectively adjacent sections along a particular chip axis. The first and third sections may be designated one dimension rule and the second section, that is adjacent to both the first and third sections, may be designated a different dimension rule.

In some embodiments, a synthesis rule to synthesize a dummy alignment-structures is provided to or incorporated within the chip-layout synthesizer. The synthesis rule may be referred to as a dummy alignment-structure synthesis rule, and may be incorporated within a placement module, a routing module, a design-rule-checking (DRC) module, and/or design rule library that can be used by one or more of the aforementioned modules. The dummy alignment-structure synthesis rule may specify that a dummy alignment structure, if provided or included within one of the several sections of the chip, employ the dimension rule that is designated for that particular section.

For example, if the first variant dimension rule is designated to a particular section, the semiconductor layers and/or metal lines included within a dummy alignment structure provided within that section may be designed/fabricated using the first variant dimension rule. The dummy alignment-structure synthesis rule does not mandate that one or more dummy alignment structures be provided or synthesized in any particular section, or in any section at all.

The use of variant/modified design rules can significantly improve the current chip-fabrication processes. In particular, the use of the variant/modified design rules for alignment of wafers, chips, and/or sections thereof can minimize or even avoid the use of or need for dummy structures used for the alignment. This can result in two benefits, as discussed above: a more accurate alignment, and/or improved utilization of the chip area for the fabrication of circuitry that is not dummy, but implements, at least in part, one or more desired functions of the chip. An additional advantage of the use of the variant/modified design rules for alignment is that the placement and/or routing of circuitry of the chip can be simplified because no or relatively fewer traditional dummy structures are required on the chip. This independently and/or in combination with the more accurate alignment facilitated by the use of the variant/modified design rules can improve the chip-manufacturing yield, and can enable the fabrication of complex chips.

The chip manufacturer, in addition to or instead of the chip designer(s) and/or chip-design tool supplier(s), may specify and/or modify one or more of the design rules at the production time. While not necessary, the chip manufacturer may include one or more dummy alignment structures, and/or may specify the alignment sections and/or subsections. The chip-design tool suppliers may provide design rules as described herein and/or the sectioning of the chip. In addition, they may device specifications, data formats, and/or presentations in their chip-design tools and/or resulting design files to accommodate additions and/or modifications of the design rules by the chip manufacturer for production optimization purposes, e.g., to optimize the production yield, and without altering functional circuitry layout of the chip.

In another aspect, a system is provided for aligning an object, e.g., a semiconductor chip and/or a wafer. The system may be computationally efficient, in that it may decrease processor or memory utilization. The system includes a first processor and a memory that is coupled to the first processor and that includes instructions that can program a processing unit to perform operations specified by the instructions. The processing unit may include the first processor or a second processor that is configured to receive the instructions from the memory under direction of the first processor. The instructions program the processing unit to perform operations according to one or more methods described above.

In yet another aspect, a semiconductor chip may be manufactured or fabricated according to one or more methods described above. The semiconductor chip corresponds to a specified functional circuitry layout. The circuitry may include logic elements, generally known as logic gates, arithmetic components, memory components such as registers, static random access memory (SRAM), dynamic RAM (DRAM), read only memory (ROM), selection, multiplexing, switching, routing, and interconnection/wiring elements, and/or analog elements. The functional circuitry layout specifies the organization of the circuitry elements within the semiconductor chip e.g., using formats such as GDSII (Graphic Data System II), OASIS (Open Artwork System Interchange Standard), CIF (Caltech Intermediate Form), LEF/DEF (Library Exchange Format/Design Exchange Format), MEBES (Manufacturing Electron Beam Exposure System), etc.

A complete layout for another semiconductor chip that also corresponds to the specified functional layout but that is not manufactured according to any of the above-described methods may include N dummy alignment structures, where N≥1. The semiconductor chip manufactured/fabricated according to any of the above-described methods, however, is either devoid of any dummy alignment structures altogether, or includes fewer, M dummy alignment structures than the other semiconductor chip, i.e., M<N.

It is clear that there are many ways to configure the device and/or system components, interfaces, communication links, and methods described herein. The disclosed methods, devices, and systems can be deployed on convenient processor platforms, including network servers, personal and portable computers, and/or other processing platforms. Other platforms can be contemplated as processing capabilities improve, including personal digital assistants, computerized watches, cellular phones and/or other portable devices. The disclosed methods and systems can be integrated with known network management systems and methods. The disclosed methods and systems can operate as an SNMP agent, and can be configured with the IP address of a remote machine running a conformant management platform. Therefore, the scope of the disclosed methods and systems are not limited by the examples given herein, but can include the full scope of the claims and their legal equivalents.

The methods, devices, and systems described herein are not limited to a particular hardware or software configuration, and may find applicability in many computing or processing environments. The methods, devices, and systems can be implemented in hardware or software, or a combination of hardware and software. The methods, devices, and systems can be implemented in one or more computer programs, where a computer program can be understood to include one or more processor executable instructions. The computer program(s) can execute on one or more programmable processing elements or machines, and can be stored on one or more storage medium readable by the processor (including volatile and non-volatile memory and/or storage elements), one or more input devices, and/or one or more output devices. The processing elements/machines thus can access one or more input devices to obtain input data, and can access one or more output devices to communicate output data. The input and/or output devices can include one or more of the following: Random Access Memory (RAM), Redundant Array of Independent Disks (RAID), floppy drive, CD, DVD, magnetic disk, internal hard drive, external hard drive, memory stick, or other storage device capable of being accessed by a processing element as provided herein, where such aforementioned examples are not exhaustive, and are for illustration and not limitation.

The computer program(s) can be implemented using one or more high level procedural or object-oriented programming languages to communicate with a computer system; however, the program(s) can be implemented in assembly or machine language, if desired. The language can be compiled or interpreted.

As provided herein, the processor(s) and/or processing elements can thus be embedded in one or more devices that can be operated independently or together in a networked environment, where the network can include, for example, a Local Area Network (LAN), wide area network (WAN), and/or can include an intranet and/or the Internet and/or another network. The network(s) can be wired or wireless or a combination thereof and can use one or more communications protocols to facilitate communications between the different processors/processing elements. The processors can be configured for distributed processing and can utilize, in some embodiments, a client-server model as needed. Accordingly, the methods, devices, and systems can utilize multiple processors and/or processor devices, and the processor/processing element instructions can be divided amongst such single or multiple processor/devices/processing elements.

The device(s) or computer systems that integrate with the processor(s)/processing element(s) can include, for example, a personal computer(s), workstation (e.g., Dell, HP), personal digital assistant (PDA), handheld device such as cellular telephone, laptop, handheld, or another device capable of being integrated with a processor(s) that can operate as provided herein. Accordingly, the devices provided herein are not exhaustive and are provided for illustration and not limitation.

References to “a processor”, or “a processing element,” “the processor,” and “the processing element” can be understood to include one or more microprocessors that can communicate in a stand-alone and/or a distributed environment(s), and can thus can be configured to communicate via wired or wireless communications with other processors, where such one or more processor can be configured to operate on one or more processor/processing elements-controlled devices that can be similar or different devices. Use of such “microprocessor,” “processor,” or “processing element” terminology can thus also be understood to include a central processing unit, an arithmetic logic unit, an application-specific integrated circuit (IC), and/or a task engine, with such examples provided for illustration and not limitation.

Furthermore, references to memory, unless otherwise specified, can include one or more processor-readable and accessible memory elements and/or components that can be internal to the processor-controlled device, external to the processor-controlled device, and/or can be accessed via a wired or wireless network using a variety of communications protocols, and unless otherwise specified, can be arranged to include a combination of external and internal memory devices, where such memory can be contiguous and/or partitioned based on the application. For example, the memory can be a flash drive, a computer disc, CD/DVD, distributed memory, etc. References to structures include links, queues, graphs, trees, and such structures are provided for illustration and not limitation. References herein to instructions or executable instructions, in accordance with the above, can be understood to include programmable hardware.

Although the methods and systems have been described relative to specific embodiments thereof, they are not so limited. As such, many modifications and variations may become apparent in light of the above teachings. Many additional changes in the details, materials, and arrangement of parts, herein described and illustrated, can be made by those skilled in the art. Accordingly, it will be understood that the methods, devices, and systems provided herein are not to be limited to the embodiments disclosed herein, can include practices otherwise than specifically described, and are to be interpreted as broadly as allowed under the law.

Accordingly, we claim:

1. A method for translationally aligning an object to a reference frame, the method comprising:
obtaining from a region of the object a first image, the first image comprising:
a first-axis first pattern of elements spaced apart along a first-axis first grid having a first-axis first period P0_0; and
a first-axis second pattern of elements spaced apart along a first-axis second grid having a first-axis second period P0_1;
wherein the first-axis first and second patterns are adjacent and correspond, respectively, to a first-axis first section of the region and a first-axis second section of the region, the first-axis first and second sections being adjacent along the first axis;
generating a first-axis moire pattern corresponding to a superimposition of a first-axis reference pattern of elements, spaced apart along the first axis and periodically at a first-axis reference period P0_r, with the first image;
measuring a first-axis moire pattern distance between:
a first-pattern first peak within the first-axis moire pattern; and
a second-pattern first peak within the first-axis moire pattern; and
determining a first-axis displacement for aligning the object to the reference frame along the first axis based on the first-axis moire pattern distance.

2. The method of claim 1, wherein a size of the region is same as a size of the object.

3. The method of claim 1, wherein the object comprises a semiconductor wafer and the region comprises: (i) two or more chips from a plurality of chips on the wafer; or (ii) one chip from the plurality of chips on the wafer.

4. The method of claim 1, wherein the elements of the first-axis first and second patterns comprise metal lines or semiconductor layers.

5. The method of claim 1, wherein the first-axis reference period Por is selected based on the first-axis first period P0_0, or the first-axis second period P0_1, or both the first-axis first and second periods.

6. The method of claim 1, further comprising:
designating for the first-axis first section the first-axis first period P0_0; or
designating for the first-axis second section the first-axis second period P0_1.

7. The method of claim 1, further comprising, prior to determining the first-axis displacement:
updating the first-axis moire pattern distance based on an additional distance between:
a first-pattern second peak within the first-axis moire pattern; and
a second-pattern second peak within the first-axis moire pattern.

8. The method of claim 1, further comprising:
obtaining from the region a second image, the second image comprising:
a second-axis first pattern of elements spaced apart along a second-axis first grid having a second-axis first period P1_0; and
a second-axis second pattern of elements spaced apart along a second-axis second grid having a second-axis second period P1_1;
wherein the second-axis first and second patterns are adjacent and correspond, respectively, to a second-axis first section of the region and a second-axis second section of the region, the second-axis first and second sections being adjacent along the second axis;
generating a second-axis moire pattern corresponding to a superimposition of a second-axis reference pattern of elements, spaced apart along the second axis and periodically at a second-axis reference period P1_r, with the second image;
measuring a first second-axis moire pattern distance between:
a second-axis first-pattern first peak within the second-axis moire pattern; and
a second-axis second-pattern first peak within the second-axis moire pattern; and
determining a second-axis displacement for aligning the object to the reference frame along the second axis based on the first second-axis moire pattern distance.

9. (canceled)

10. (canceled)

11. (canceled)

12. The method of claim 1, wherein the first-axis first pattern or the first-axis second pattern is aperiodic.

13. A method for rotationally aligning an object to a reference frame, the method comprising:
obtaining an image from a region of the object, the image comprising a first-axis observed pattern of elements disposed over a first-axis grid along a first axis and having a first-axis period P0, wherein the first-axis observed pattern is aperiodic;
selecting a first-axis reference period Por, such that a first-axis moire pattern corresponding to a superimposition of a first-axis reference pattern of elements, spaced apart periodically along the first axis and at the first-axis reference period Por, with the first-axis observed pattern, is measurable at a specified sensitivity;
superimposing the first-axis reference pattern with the first-axis observed pattern to yield the first-axis moire pattern;
measuring a first-axis spacing or first-axis angle of moire lines from the first-axis moire pattern; and
computing from the first-axis spacing or the first-axis angle of moire lines an angular displacement for rotationally aligning the object to the reference frame.

14. The method of claim 13, wherein a size of the region is same as a size of the object.

15. The method of claim 13, wherein the object comprises a semiconductor wafer and the region comprises: (i) two or more chips from a plurality of chips on the wafer; or (ii) one chip from the plurality of chips on the wafer.

16. (canceled)

17. The method of claim 13, wherein the image comprises a second-axis observed pattern of elements disposed over a second-axis grid along a second axis and having a second-axis period P1, the method further comprising:
selecting a second-axis reference period P1r, such that a second-axis moire pattern corresponding to a superimposition of a second-axis reference pattern of elements, spaced apart periodically along the second axis and at the second-axis reference period P1r, with the second-axis observed pattern, is measurable at the specified sensitivity; and
superimposing the second-axis reference pattern with the second-axis observed pattern to yield the second-axis moire pattern;
measuring a second-axis spacing or a second-axis angle of moire lines from the second-axis moire pattern,
wherein computing the angular displacement is further based on, at least in part, the second-axis spacing of moire lines or the second-axis angle of moire lines.

18. (canceled)

19. (canceled)

20. (canceled)

21. A method for employing one or more design rules for fabricating computer chips, the method comprising:
obtaining, for a particular parameter of chip elements of a particular type, a set of design rules comprising an original dimension rule and a first variant dimension rule obtained by varying the original dimension rule within a moire limit;
dividing a chip to be fabricated into a plurality of adjacent sections along a selected chip axis, the plurality of adjacent sections comprising a first section and a second section; and
designating for the particular parameter of the chip elements of the particular type, from the set of design rules: (i) for the first section, a first selected dimension rule, and (ii) for the second section, a second selected dimension rule that is different from the first selected dimension rule.

22. The method of claim 21, wherein:
the first selected dimension rule comprises the original dimension rule; and
the second selected dimension rule comprises the first variant dimension rule.

23. The method of claim 21, wherein:
the set of design rules comprises a second variant dimension rule obtained by varying the original dimension rule within the moire limit, wherein the second variant dimension rule is different from the first variant dimension rule;
the first selected dimension rule comprises the first variant dimension rule; and
the second selected dimension rule comprises the second variant dimension rule.

24. The method of claim 21, wherein the particular type of the chip elements is selected from the group consisting of a metal line, a p-type semiconductor layer, an n-type semiconductor layer, a polycrystalline semiconductor layer, a p-type well layer, an n-type well layer, and an undoped semiconductor layer.

25. (canceled)

26. (canceled)

27. (canceled)

28. (canceled)

29. (canceled)

30. (canceled)

31. (canceled)

32. (canceled)

33. (canceled)

34. A method for facilitating chip alignment via a chip-layout synthesizer by providing thereto one or more variant design rules for fabricating computer chips, the method comprising:
selecting, for a particular parameter of chip elements of a particular type, an original design rule comprising an original dimension rule; and
incorporating within the chip-layout synthesizer, a first variant dimension rule obtained by varying the original dimension rule within a moire limit.

35. The method of claim 34, wherein the particular type of the chip elements is selected from the group consisting of a metal line, a p-type semiconductor layer, an n-type semiconductor layer, a polycrystalline semiconductor layer, a p-type well layer, an n-type well layer, and an undoped semiconductor layer.

36. The method of claim 34, wherein the particular parameter is selected from the group consisting of a width of an instance of the chip elements of the particular type, a spacing along a selected chip axis between two consecutive instances of the chip elements of the particular type, to be placed along the selected chip axis, and a spacing along the selected chip axis between respective centerlines of two consecutive instances of the chip elements of the particular type, the two instances to be placed along the selected chip axis.

37. (canceled)

38. (canceled)

39. (canceled)

40. (canceled)

41. (canceled)

42. (canceled)

43. (canceled)
